(19) United States
(12) Patent Application Publication
(10) Pub. No.: US 2026/0128111 A1
(43) Pub. Date: May 7, 2026

(54) NON-VOLATILE MEMORY DEVICE PERFORMING WRITE TRAINING

(71) Applicant: SAMSUNG ELECTRONICS CO., LTD., Suwon-si (KR)

(72) Inventors: Seonghyeog Choi, Suwon-si (KR); Changkyu Seol, Suwon-si (KR); Miryeong Seol, Suwon-si (KR); Yuseok Song, Suwon-si (KR); Taemin Lee, Suwon-si (KR); Youngdon Choi, Suwon-si (KR)

(73) Assignee: SAMSUNG ELECTRONICS CO., LTD., Suwon-si (KR)

(21) Appl. No.: 19/272,256

(22) Filed: Jul. 17, 2025

(30) Foreign Application Priority Data
Nov. 1, 2024 (KR) 10-2024-0153790

(51) Int. Cl. G11C 29/12; G11C 29/20; G11C 29/36

(52) U.S. Cl. CPC G11C 29/1201; G11C 29/12015; G11C 29/20; G11C 29/36; G11C 2029/3602

(57) ABSTRACT

Provided is a non-volatile memory device performing write training. The non-volatile memory device includes a plurality of memory dies connected to a controller through a first channel and configured to perform write training based on training data received from the controller. The plurality of memory dies include a first memory die and a second memory die each comprising non-volatile memory cells. The first memory die receives first training data from the controller in a first interval, compares the first training data with first pattern data in a second interval, and transmits a first pass/fail value regarding the first training data to the controller. The second memory die receives second training data from the controller in the second interval.

### CROSS-REFERENCE TO RELATED APPLICATION

This application is based on and claims priority under 35 U.S.C. § 119 to Korean Patent Application No. 10-2024-0153790, filed on Nov. 1, 2024, in the Korean Intellectual Property Office, the disclosure of which is incorporated herein in its entirety by reference.

### BACKGROUND

One or more example embodiments of the disclosure relate to a memory device, and more particularly, to a non-volatile memory device performing write training and a method for write training of a non-volatile memory.

A storage device may include a non-volatile memory and a controller that controls the non-volatile memory. Since the non-volatile memory and the controller have different operational characteristics, initialization or training may be needed during an initial operation of the storage device or the initial operation between the non-volatile memory and the controller. In particular, a training operation may be performed to ensure the reliability of data transmitted and received between the non-volatile memory and the controller. Since data is transmitted and received between the non-volatile memory and the controller based on training parameters obtained through training operations, it may be important to obtain accurate training parameters.

### SUMMARY

One or more example embodiments of the disclosure provide a non-volatile memory device capable of reducing a write training operation time and a write training method of the non-volatile memory device.

According to an aspect of the disclosure, there is provided a non-volatile memory device including a plurality of memory dies connected to a controller through a first channel and configured to perform write training based on training data received from the controller, wherein the plurality of memory dies include a first memory die and a second memory die each including non-volatile memory cells, the first memory die is configured to receive first training data from the controller in a first interval and compare the first training data with first pattern data and transmits a first pass/fail value regarding the first training data to the controller in a second interval after the first interval, and the second memory die is configured to receive second training data from the controller in the second interval.

According to another aspect of the disclosure, there is provided a non-volatile memory device including a buffer chip connected to a controller through a first channel, and a plurality of memory dies connected to the buffer chip through a second channel and configured to perform a first write training between the controller and the buffer chip during a first write training interval, wherein the plurality of memory dies include a first memory die configured to receive first training data corresponding to a first delay value from the controller through the buffer chip during a first interval of the first write training interval, and a second memory die configured to receive second training data corresponding to a second delay value different from the first delay value from the controller through the buffer chip during a second interval of the first write training interval, and the first memory die generates a first pass/fail value for the first training data and transmits the first pass/fail value to the controller through the buffer chip, during the second interval of the first write training interval.

According to another aspect of the disclosure, there is provided a non-volatile memory device including a plurality of memory dies connected to a controller through a first channel and configured to perform write training based on training data received from the controller, wherein the plurality of memory dies include a first memory die including a first page buffer and configured to store reference training data and first training data received from the controller in the first page buffer and generate a first pass/fail value regarding the first training data based on a result of a logical operation for the reference training data and the first training data, and a second memory die including a second page buffer and configured to store the reference training data and second training data received from the controller in the second page buffer and generate a second pass/fail value regarding the second training data based on a result of a logical operation for the reference training data and the second training data, and, while the first memory die generates the first pass/fail value, the second memory die receives the reference training data or the second training data.

According to another aspect of the disclosure, there is provided a non-volatile memory device including a plurality of memory dies connected to a controller through a first channel, wherein the plurality of memory dies include a first memory die including a first page buffer and configured to receive first training data from the controller through the first channel during a first interval and store the received first training data in the first page buffer, and a second memory die including a second page buffer and configured to receive second training data from the controller through the first channel during a second interval after the first interval and store the received second training data in the second page buffer, and the first memory die generates a first pass/fail value regarding the first training data during the second interval and transmits the first pass/fail value to the controller through the first channel.

According to another aspect of the disclosure, there is provided a non-volatile memory device including a plurality of memory dies connected to a controller through a first channel, wherein the plurality of memory dies comprise: a first memory die comprising a first page buffer and configured to receive first training data from the controller through the first channel during a first interval and store the received first training data in the first page buffer; and a second memory die comprising a second page buffer and configured to receive second training data from the controller through the first channel during a second interval after the first interval and store the received second training data in the second page buffer, and the first memory die is configured to generate a first pass/fail value regarding the first training data and transmit the first pass/fail value to the controller through the first channel, during the second interval.

### BRIEF DESCRIPTION OF DRAWINGS

Example embodiments of the disclosure will be more clearly understood from the following detailed description taken in conjunction with the accompanying diagrams.

FIG. 1 is a block diagram showing a storage device according to one or more embodiments.

FIG. 2 is a block diagram showing a memory die according to one or more embodiments.

FIG. 3 is a block diagram showing a storage device according to one or more embodiments.

FIG. 4 is a block diagram showing a storage device according to one or more embodiments.

FIG. 5 is a block diagram showing a storage device according to one or more embodiments.

FIG. 6 is a timing diagram illustrating a write training operation of a first memory die and a second memory die of FIG. 5, according to one or more embodiments.

FIG. 7 is a timing diagram illustrating an example of a write training operation of a first memory die and a second memory die of FIG. 5, according to one or more embodiments.

FIG. 8 is a block diagram showing a storage device according to one or more embodiments.

FIG. 9 is a timing diagram illustrating a write training operation of a first memory die and a second memory die of FIG. 8, according to one or more embodiments.

FIG. 10 is a block diagram showing a storage device according to one or more embodiments.

FIG. 11 is a timing diagram illustrating a write training operation of first to fourth memory dies of FIG. 10, according to one or more embodiments.

FIG. 12 is a timing diagram illustrating an example of a write training operation of a first memory die to a fourth memory die of FIG. 10, according to one or more embodiments.

FIGS. 13A and 13B are timing diagrams illustrating another example of a write training operation of the first to fourth memory dies of FIG. 10, according to one or more embodiments.

FIG. 14 is a timing diagram illustrating another example of a write training operation of the first to fourth memory dies of FIG. 10, according to one or more embodiments.

FIG. 15 is a block diagram showing a storage device according to one or more embodiments.

FIG. 16 is a timing diagram illustrating an example of a write training operation of first to fourth memory dies of FIG. 15, according to one or more embodiments.

FIG. 17 is a timing diagram illustrating another example of a write training operation of the first to fourth memory dies of FIG. 15, according to one or more embodiments.

FIG. 18 is a block diagram showing a controller according to one or more embodiments.

FIG. 19 is a block diagram showing a storage device according to one or more embodiments of the disclosure; and

FIG. 20 is a block diagram showing a storage device according to one or more embodiments.

FIG. 21 is a timing diagram illustrating a write training operation of a first memory die and a second memory die of FIG. 20, according to one or more embodiments.

FIG. 22 is a block diagram showing a storage device according to one or more embodiments.

FIG. 23 is a timing diagram illustrating an example of a write training operation of first to fourth memory dies of FIG. 22, according to one or more embodiments.

FIG. 24 is a block diagram showing a memory die according to one or more embodiments.

FIG. 25 is a block diagram showing a storage device according to one or more embodiments.

FIG. 26 is a timing diagram illustrating a write training operation of a first memory die and a second memory die of FIG. 25, according to one or more embodiments.

FIG. 27 is a flowchart showing a method of operating a non-volatile memory, according to one or more embodiments.

FIG. 28 is a flowchart showing an operation method between a controller, a first memory die, and a second memory die, according to one or more embodiments.

FIG. 29 is a flowchart showing a method of operating a non-volatile memory, according to one or more embodiments.

### DETAILED DESCRIPTION

Hereinafter, with reference to the accompanying drawings, various embodiments of the disclosure are described in detail and thus a person of ordinary skill in the art to which the disclosure belongs can easily practice the disclosure. The disclosure may be implemented in many different forms and is not limited to the embodiments described herein.

In order to clearly describe the disclosure, parts that are not related to the description have been omitted, and the same reference symbols are used for identical or similar components throughout the specification.

In addition, unless explicitly described to the contrary, the word “comprise”, and variations such as “comprises” or “comprising”, will be understood to imply the inclusion of stated elements but not the exclusion of any other elements.

Expressions such as “at least one of”, when preceding a list of elements, modify the entire list of elements and do not modify the individual elements of the list. For example, the expression, “at least one of a, b, and c” (or “at least one of a, b, or c”) should be understood as including only a, only b, only c, both a and b, both a and c, both b and c, or all of a, b, and c.

The terms “module” and “unit” used in this document are terms used to refer to a component that performs at least one function or operation, and such a component may be implemented as hardware or software, or as a combination of hardware and software.

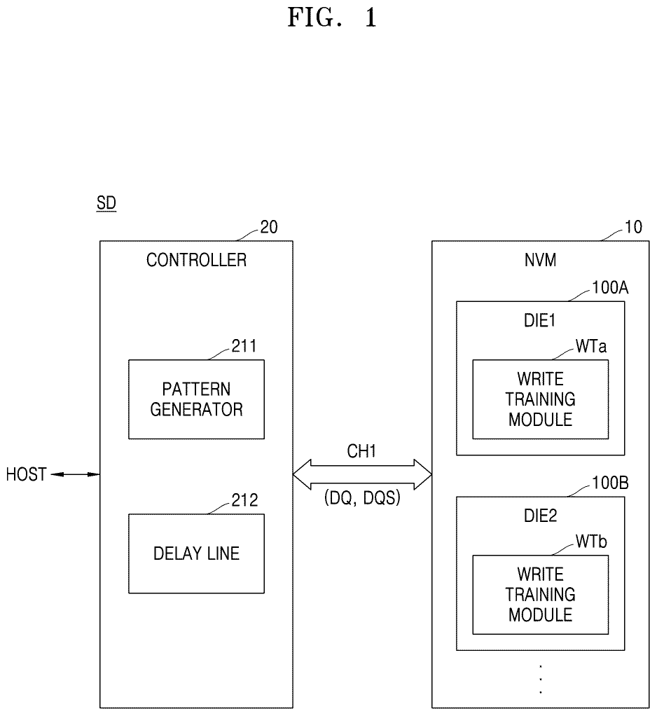

FIG. 1 is a block diagram showing a storage device SD according to one or more embodiments.

Referring to FIG. 1, the storage device SD may include a non-volatile memory 10 and a controller 20. The non-volatile memory 10 and the controller 20 may communicate with each other through a first channel CH1, and a data signal DQ, a data strobe signal DQS, etc. may be transmitted through the first channel CH1. The non-volatile memory 10 may include a plurality of memory dies including a first memory die 100A and a second memory die 100B, and thus the non-volatile memory 10 may be referred to as a multi-die memory, a multi-chip memory, or a memory package. For example, the non-volatile memory 10 may be a Dual Die Package (DDP) or a Quadruple Die Package (QDP), but the disclosure is not limited thereto. According to the embodiment, the storage device SD may be referred to as a memory system, and the controller 20 may be referred to as a memory controller or a storage controller.

The controller 20 may control the non-volatile memory 10 to read data stored in the non-volatile memory 10 or to program data into the non-volatile memory 10, in response to a read/program request received from a host HOST. The controller 20 may control program, read, and erase operations for the non-volatile memory 10 by providing commands and addresses to the non-volatile memory 10. Also, programming data and read data may be transmitted and received between the controller 20 and the non-volatile memory 10.

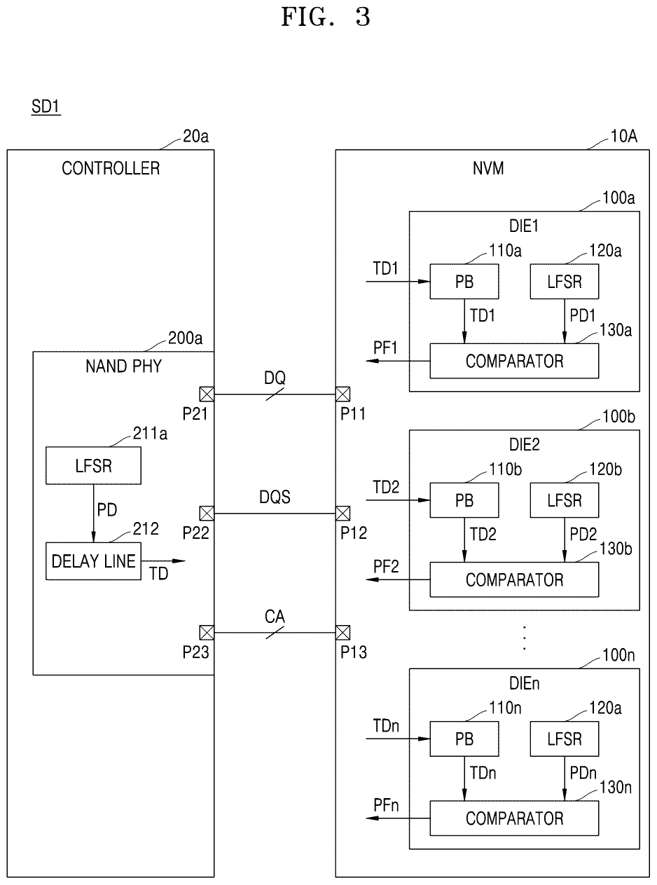

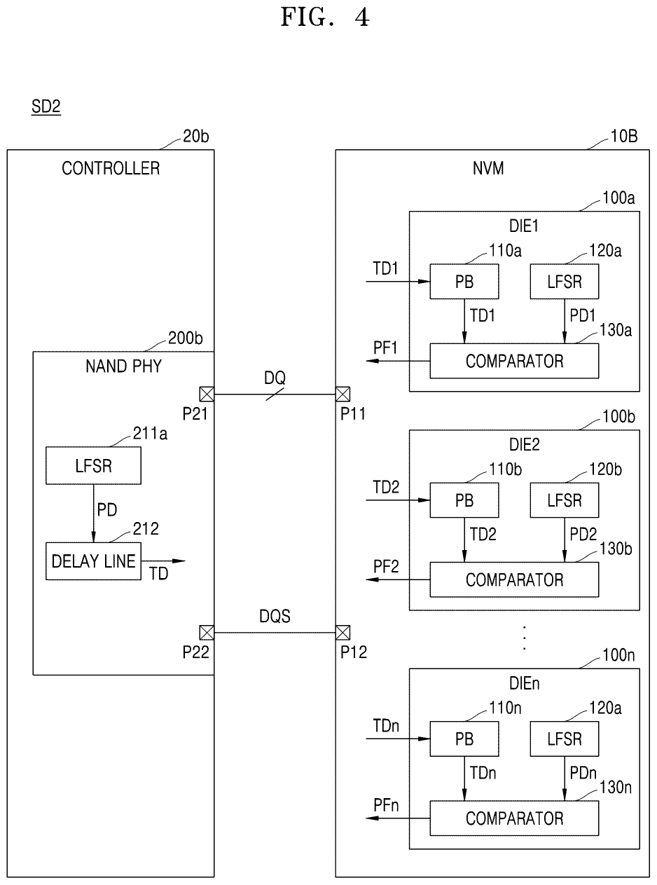

According to one or more embodiments, the non-volatile memory 10 and the controller 20 may communicate with each other in a Separate Command Address (SCA) manner in which commands and addresses are transmitted separately from data. For example, commands and addresses may be transmitted via a line for a command/address signal (e.g., CA of FIG. 3) in synchronization with a command/address clock signal, and data may be transmitted via a line for a data signal DQ in synchronization with a data strobe signal DQS, as described below with reference to FIG. 3. According to one or more embodiments, commands, addresses, and data may be transmitted via a data signal DQ, and the data signal DQ may be transmitted via a line for the data signal DQ in synchronization with a data strobe signal DQS, as described below with reference to FIG. 4.

The non-volatile memory 10 and the controller 20 may be connected to each other through a plurality of pins, and training may be performed on data transmitted and received through the plurality of pins during an initialization or a training operation. Write training represents an operation of aligning the data signal DQ with the data strobe signal DQS. When the controller 20 performs write training, the controller 20 may detect a center of the data signal DQ by repeatedly programming and reading training patterns and/or training data according to various delay values into and from the non-volatile memory 10.

In detail, a program operation in which the controller 20 transmits training data to the non-volatile memory 10 may be performed, a read operation in which the controller 20 receives read data from the non-volatile memory 10 may be subsequently performed, and a comparison operation in which the controller 20 compares training data with read data to determine whether the training data passes/fails may be subsequently performed. At this time, the read operation and the comparison operation may take a considerable amount of time. Also, when the non-volatile memory 10 includes a plurality of memory dies, a write training operation needs to be performed on each of the plurality of memory dies, and thus time required to perform the write training operation may significantly increase as a number of memory dies increases.

However, according to one or more embodiments, the plurality of memory dies included in the non-volatile memory 10 may each include a write training module that performs write training. Therefore, each memory die may generate a pass/fail value by determining whether training data passes/fails and transmit the generated pass/fail value to the controller 20. Therefore, the controller 20 does not need to perform a read operation and a comparison operation during write training, and thus write training operation time may be significantly reduced. Also, by performing write training operations for a plurality of memory dies included in the non-volatile memory 10 in an interleaving manner, the write training operation time may not significantly increase even when the number of memory dies increases. Detailed descriptions thereof will be given below.

The controller 20 may include a pattern generator 211 and a delay line 212. The pattern generator 211 may generate training patterns or training data for write training. The delay line 212 may output a data strobe signal DQS and a data signal DQ including training data according to a pre-set delay value. Each of the plurality of memory dies included in the non-volatile memory 10 may include a write training module, and the write training module may determine whether training data received from the controller 20 is a pass or a fail.

The first memory die 100A may include a write training module WTa, and the second memory die 100B may include a write training module WTb. In certain situations, such as booting or initialization, write training modules WTa and WTb may each receive training data from the controller 20 and perform write training to determine pass/fail of received training data. In detail, each of the write training modules WTa and WTb may generate a pass/fail value indicating whether training data is pass/fail by comparing the training data to pattern data. In this way, the write training modules WTa and WTb may each directly determine whether training data is pass/fail and transmit a pass/fail value to the controller 20 as small-sized data, e.g., 1-byte data. Therefore, the controller 20 does not need to perform a read operation on training data stored in each of a plurality of memory dies during write training, and thus the write training operation time may be significantly reduced.

According to one or more embodiments, while the write training module WTa of the first memory die 100A generates pattern data and performs a comparison operation for comparing training data with the pattern data, an operation for transmitting the training data to the second memory die 100B may be performed. According to one or more embodiments, while the write training module WTa of the first memory die 100A performs an operation for generating a pass/fail value, an operation for transmitting training data to the second memory die 100B may be performed. In this way, by performing write training on a plurality of memory dies in an interleaving manner, the write training operation time may be significantly reduced.

According to some embodiments, the storage device SD may be an internal memory embedded in an electronic device. For example, the storage device SD may be, for example but not limited to, a solid state drive (SSD), an embedded universal flash storage (UFS) memory device, or an embedded multi-media card (eMMC). According to some embodiments, the storage device SD may be an external memory that may be detachably attached to an electronic device. For example, the storage device SD may, for example but not limited to, be a UFS memory card, a compact flash (CF) card, a secure digital (SD) card, a micro secure digital (SD) card, a mini secure digital (SD) card, an extreme digital (xD) card, or a memory stick.

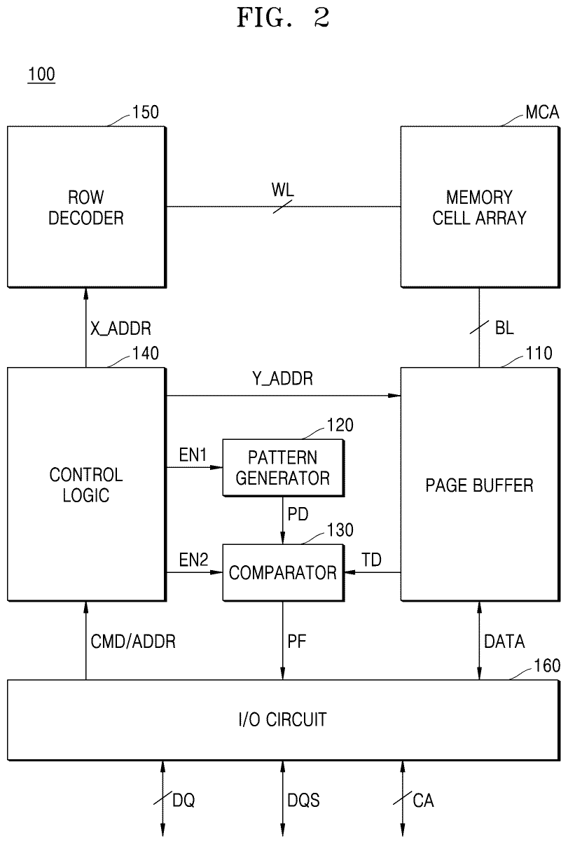

FIG. 2 is a block diagram showing a memory die 100 according to one or more embodiments.

Referring to FIGS. 1 and 2 together, the memory die 100 may include a memory cell array MCA, a page buffer 110, a pattern generator 120, a comparator 130, a control logic 140, a row decoder 150, and an input/output circuit 160. For example, the memory die 100 may correspond to the first memory die 100A or the second memory die 100B of FIG. 1. For example, the page buffer 110, the pattern generator 120, and the comparator 130 may constitute or be included in the write training module WTa or the write training module WTb of FIG. 1.

Although the pattern generator 120 and the comparator 130 are illustrated as separate components in FIG. 2, the disclosure is not limited thereto. According to some embodiments, the pattern generator 120 may be included in the comparator 130. According to some embodiments, the pattern generator 120 and the comparator 130 may be included in the control logic 140. According to some embodiments, the pattern generator 120 and the comparator 130 may be included in the input/output circuit 160.

The memory cell array MCA may include a plurality of non-volatile memory cells. For example, the plurality of non-volatile memory cells may be NAND flash memory cells. According to some embodiments, the plurality of non-volatile memory cells may be resistive memory cells such as resistive RAM (ReRAM) cells, phase change RAM (PRAM) cells, or magnetic RAM (MRAM) cells. However, the disclosure is not limited thereto, and, according to some embodiments, the memory cell array MCA may include volatile memory cells, such as dynamic random access memory (DRAM) cells or static random access memory (SRAM) cells.

In an example embodiment, the memory cell array MCA may include a three-dimensional memory cell array, and the three-dimensional memory cell array may include a plurality of cell strings or a plurality of NAND strings. Each cell string may include memory cells connected to word lines vertically stacked on a substrate, respectively. U.S. Pat. Nod. 7,679,133, 8,553,466, 8,654,587, 8,559,235, and U.S. Patent Application Publication No. 2011/0233648 are incorporated herein by reference.

According to one or more embodiments, referring to FIGS. 1 and 2, the input/output circuit 160 may receive a data signal DQ and a data strobe signal DQS from the controller 20, and/or transmit a data signal DQ and a data strobe signal DQS to the controller 20. For example, commands CMD, addresses ADDR, and data DATA may be transmitted through the data signal DQ. According to one or more embodiments, the input/output circuit 160 may receive a command/address signal CA, a data signal DQ, and a data strobe signal DQS from the controller 20, and/or transmit a command/address signal CA, a data signal DQ, and a data strobe signal DQS to the controller 20. For example, data DATA may be transmitted via a data signal DQ, and a command CMD and an address ADDR may be transmitted via a command/address signal CA.

The control logic 140 may output various control signals for programming data into the memory cell array MCA or reading data from the memory cell array MCA based on the command CMD and address ADDR received from the controller 20. Therefore, the control logic 140 may overall control various operations within the memory die 100. In detail, the control logic 140 may provide a row address X_ADDR to the row decoder 150 and provide a column address Y_ADDR to the page buffer 110.

The row decoder 150 may select one of a plurality of word lines WL in response to the row address X_ADDR. For example, during a program operation, the row decoder 150 may apply a program voltage to a selected word line in a program execution interval and apply a program verify voltage to the selected word line in a program verify interval. The page buffer 110 may select at least one bit line BL from among a plurality of bit lines BL in response to the column address Y_ADDR. The page buffer 110 may operate as a write driver or a sense amplifier depending on an operation mode.

According to the present embodiment, the page buffer 110 may be used as a buffer for storing training data TD during write training. During write training, the training data TD may be stored in the page buffer 110 and then output without having to be stored in the memory cell array MCA. In this regard, by using the page buffer 110 for write training, the controller 20 may perform write training using a training pattern having a long length, e.g., several kilobytes.

The pattern generator 120 may generate pattern data PD to be used for writing training and provide the generated pattern data PD to the comparator 130. For example, the pattern generator 120 may include a linear feedback shift register (LFSR). The comparator 130 may determine whether the training data TD is pass/fail by comparing the training data TD received from the page buffer 110 with the pattern data PD received from the pattern generator 120 during write training.

During writing training, the input/output circuit 160 may receive a first command and an address that instruct a program operation from the controller 20 through the data signal DQ or the command/address signal CA and may transmit the received first command and the received address to the control logic 140. For example, the first command may be a data input command or a program command. Next, the input/output circuit 160 may receive training data TD from the controller 20 through the data signal DQ and transmit received training data TD to the page buffer 110.

Next, the input/output circuit 160 may receive a second command instructing a comparison operation from the controller 20 through the data signal DQ or the command/address signal CA and may transmit the received second command to the control logic 140. The control logic 140 may generate a first enable signal EN1 and a second enable signal EN2 in response to the second command and transmit the first enable signal EN1 and the second enable signal EN2 to the pattern generator 120 and the comparator 130, respectively. According to some embodiments, the first enable signal EN1 and the second enable signal EN2 may be the same signals.

The pattern generator 120 may generate the pattern data PD in response to the first enable signal EN1 and provide the pattern data PD to the comparator 130. The comparator 130 may compare the pattern data PD with the training data TD in response to the second enable signal EN2, and generate a pass/fail value PF based on a comparison result.

For example, when the training data TD corresponds to the pattern data PD, the comparator 130 may determine that the training data TD is pass and generate the pass/fail value PF at a first logic level. For example, when the training data TD does not correspond to the pattern data PD, the comparator 130 may determine that the training data TD is fail and generate the pass/fail value PF at a second logic level.

Next, the input/output circuit 160 may receive a third command requesting a pass/fail value from the controller 20 through the data signal DQ or the command/address signal CA and may transmit the received third command to the control logic 140. For example, the third command may be a status read command. The control logic 140 may control the comparator 130 and the input/output circuit 160 to output the pass/fail value PF in response to the third command. For example, the memory die 100 may further include a register, which may store the pass/fail value PF generated by the comparator 130. At this time, the control logic 140 may control the register to output the pass/fail value PF.

FIG. 3 is a block diagram showing a storage device SD1 according to one or more embodiments.

Referring to FIG. 3, the storage device SD1 may include a non-volatile memory 10A and a controller 20a, and the non-volatile memory 10A and the controller 20a may communicate with each other in an SCA manner in which commands and addresses are transmitted separately from data. The non-volatile memory 10A may correspond to an example of the non-volatile memory 10 of FIG. 1, and the controller 20a may correspond to an example of the controller 20 of FIG. 1. The non-volatile memory 10A may include first to n-th memory dies 100a to 100n, where n is a positive integer. The non-volatile memory 10A may further include a plurality of pins P11 to P13.

The non-volatile memory 10A may transmit and receive the data signal DQ to and from the controller 20a through pins P11, and thus the pins P11 may be referred to as data pins or input/output pins. The non-volatile memory 10A may transmit and receive the data strobe signal DQS to and from the controller 20a through a pin P12, and thus the pin P12 may be referred to as a data strobe pin. The non-volatile memory 10A may receive the command/address signal CA from the controller 20a through pins P13, and thus the pins P13 may be referred to as command/address pins.

According to some embodiments, the non-volatile memory 10A may further include a command/address clock pin configured to receive a command/address clock signal. According to some embodiments, the non-volatile memory 10A may further include an SCA enable pin configured to receive an SCA enable signal. The controller 20a may include a plurality of pins P21 to P23 respectively connected to the plurality of pins P11 to P13 of the non-volatile memory 10A. At this time, signal lines through which the data signal DQ, the data strobe signal DQS, and the command/address signal CA are transmitted may constitute or be included in the first channel CH1 of FIG. 1.

The controller 20a may include an LFSR 211a and a delay line 212. At this time, the LFSR 211a may correspond to an example of the pattern generator 211 of FIG. 1.

For example, the LFSR 211a and the delay line 212 may be included in a non-volatile memory interface 200a. According to one or more embodiments, the non-volatile memory 10A may include a NAND flash memory, and in this case, the non-volatile memory interface 200a may correspond to a NAND physical layer, i.e., a NAND PHY. The LFSR 211a may generate the pattern data PD having a training pattern. The delay line 212 may output the data strobe signal DQS and the pattern data PD synchronized with the data strobe signal DQS as the training data TD according to a particular delay value.

The first memory die 100a may include a page buffer 110a, an LFSR 120a, and a comparator 130a. The page buffer 110a may receive first training data TD1 from the controller 20a and store the received first training data TD1. The LFSR 120a may generate first pattern data PD1. At this time, the first pattern data PD1 may be identical to the pattern data PD generated by the LFSR 211a. The comparator 130a may generate a first pass/fail value PF1 indicating whether the first training data TD1 is pass or fail by comparing the first training data TD1 with the first pattern data PD1. According to some embodiments, the first memory die 100a may further include a register configured to store the first pass/fail value PF1.

The second memory die 100b may include a page buffer 110b, an LFSR 120b, and a comparator 130b. The page buffer 110b may receive second training data TD2 from the controller 20a and store the received second training data TD2. For example, the second memory die 100b may receive the second training data TD2 while a comparison operation of the comparator 130a of the first memory die 100a is being performed. The LFSR 120b may generate second pattern data PD2. At this time, the second pattern data PD2 may be identical to the pattern data PD generated by the LFSR 211a. The comparator 130b may generate a second pass/fail value PF2 indicating whether the second training data TD2 is pass or fail by comparing the second training data TD2 with the second pattern data PD2. An n-th memory die 100n may include a page buffer 110n, an LFSR 120n, and a comparator 130n. The operations of the page buffer 110n, the LFSR 120n, and the comparator 130n may be substantially similar to operations of the page buffer 110b, the LFSR 120b, and the comparator 130b.

At this time, LFSRs 120a to 120n may be synchronized with the LFSR 211a of the controller 20a. For example, the same initial value, i.e., a seed, may be input to LFSRs 120a to 120n and 211a, and a polynomial representing an arrangement of taps used to generate a next state may be applied to the LFSRs 120a to 120n and 211a. Therefore, the pattern data PD generated by the LFSR 211a of the controller 20a may be identical to each of the first to n-th pattern data PD1 to PDn respectively generated by the LFSRs 120a to 120n.

FIG. 4 is a block diagram showing a storage device SD2 according to one or more embodiments.

Referring to FIG. 4, the storage device SD2 may include a non-volatile memory 10B and a controller 20b. The non-volatile memory 10B may correspond to an example of the non-volatile memory 10 of FIG. 1, and the controller 20b may correspond to an example of the controller 20 of FIG. 1. The storage device SD2 may correspond to a modified example of the storage device SD1 of FIG. 3, and descriptions given above with reference to FIG. 3 may be applied to the present embodiment.

The non-volatile memory 10B may include first to n-th memory dies 100a to 100n and a plurality of pins P11 and P12. The controller 20b may include the LFSR 211a, the delay line 212, and a plurality of pins P21 and P22 respectively connected to the plurality of pins P11 and P12. For example, the LFSR 211a and the delay line 212 may be included in a non-volatile memory interface 200b or a NAND PHY. The non-volatile memory 10B may transmit and receive the data signal DQ to and from the controller 20b through the pins P11, and thus the pins P11 may be referred to as data pins or input/output pins. At this time, the data signal DQ may include a command, an address, and data. The non-volatile memory 10B may transmit and receive the data strobe signal DQS to and from the controller 20b through the pin P12, and thus the pin P12 may be referred to as a data strobe pin.

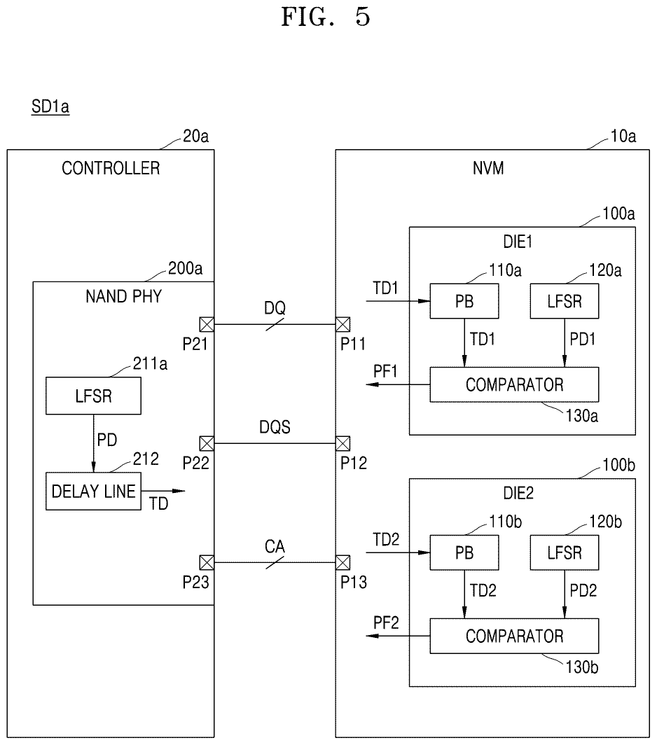

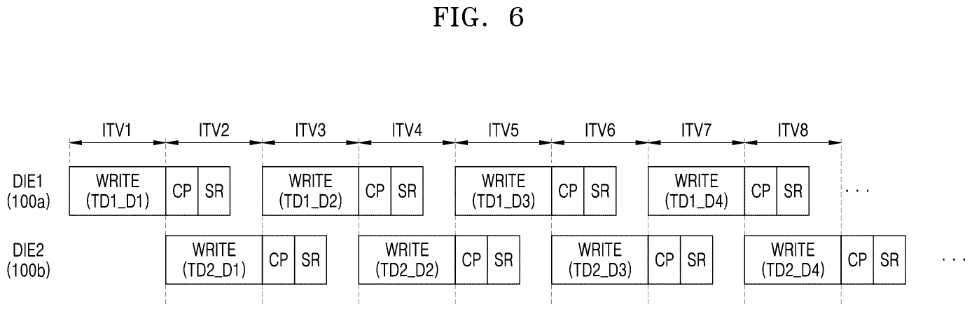

FIG. 5 is a block diagram showing a storage device SD1a according to one or more embodiments. FIG. 6 is a timing diagram illustrating a write training operation of the first memory die 100a and the second memory die 100b of FIG. 5, according to one or more embodiments.

Referring to FIGS. 5 and 6 together, the storage device SD1a may include the non-volatile memory 10a and the controller 20a. The storage device SD1a may correspond to a modified example of the storage device SD1 of FIG. 3, and descriptions given above with reference to FIGS. 1 to 3 may also be applied to the present embodiment. The non-volatile memory 10a may be a DDP including the first memory die 100a and the second memory die 100b.

A write training operation may be performed during a write training interval including a first interval ITV1 to an eighth interval ITV8. In the first interval ITV1, the first memory die 100a may perform a write operation WRITE regarding first training data TD1_D1 corresponding to a first delay value D1. In detail, the first memory die 100a may receive a first command and an address instructing a program operation from the controller 20a, subsequently receive the first training data TD1_D1, and store the received first training data TD1_D1 in the page buffer 110a. For example, the first training data TD1_D1 may correspond to a training pattern having a delay corresponding to the first delay value D1 of a delayed locked loop or a phase locked loop with respect to the data strobe signal DQS.

In the second interval ITV2, the first memory die 100a may perform a comparison operation CP for comparing the first training data TD1_D1 with the first pattern data PD1, and subsequently perform a status read operation SR for transmitting the first pass/fail value PF1 to the controller 20a. In detail, the first memory die 100a may receive a second command instructing a comparison operation. In response to a received second command, the LFSR 120a may generate the first pattern data PD1, and the comparator 130a may generate the first pass/fail value PF1 by comparing the first training data TD1_D1 with the first pattern data PD1. Also, the first memory die 100a may receive a third command requesting the first pass/fail value PF1 and transmit the first pass/fail value PF1 to the controller 20a in response to a received third command.

In the second interval ITV2, the second memory die 100b may perform a write operation WRITE regarding second training data TD2_D1 corresponding to the first delay value D1. In detail, the second memory die 100b may receive a first command and an address instructing a program operation from the controller 20a, subsequently receive the second training data TD2_D1, and store the received second training data TD2_D1 in the page buffer 110b.

In this regard, in the second interval ITV2, the comparison operation CP and the status read operation SR of the first memory die 100a and the write operation WRITE of the second memory die 100b may be performed in parallel. While the comparison operation CP and the status read operation SR are being performed in the first memory die 100a, the second training data TD2_D1 may be transmitted to the second memory die 100b through a line for the data signal DQ of the first channel CH1, and thus an idle time of the line for the data signal DQ of the first channel CH1 may be reduced. By performing write training in this interleaving manner, the write training operation time may be reduced.

In the third interval ITV3, the first memory die 100a may perform a write operation WRITE regarding first training data TD1_D2 corresponding to a second delay value D2. For example, the first training data TD1_D2 may correspond to a training pattern having a delay corresponding to the second delay value D2 of a delay locked loop (DLL) relative to the data strobe signal DQS. For example, the second delay value D2 may be greater than the first delay value D1. Also, in the third interval ITV3, the second memory die 100b may perform a comparison operation CP for comparing the second training data TD2_D1 with the second pattern data PD2 and a status read operation SR for transmitting the second pass/fail value PF2. In this regard, in the third interval ITV3, the write operation WRITE of the first memory die 100a and the comparison operation CP and the status read operation SR of the second memory die 100b may be performed in parallel.

In the fourth interval ITV4, the first memory die 100a may perform a comparison operation CP for comparing the first training data TD1_D2 with the first pattern data PD1 and a status read operation SR for transmitting the first pass/fail value PF1. Also, in the fourth interval ITV4, the second memory die 100b may perform a write operation WRITE regarding second training data TD2_D2 corresponding to the second delay value D2. In this regard, in the fourth interval ITV4, the comparison operation CP and the status read operation SR of the first memory die 100a and the write operation WRITE of the second memory die 100b may be performed in parallel.

In the fifth interval ITV5, the first memory die 100a may perform a write operation WRITE regarding first training data TD1_D3 corresponding to a third delay value D3. Also, in the fifth interval ITV5, the second memory die 100b may perform a comparison operation CP for comparing the second training data TD2_D2 with the second pattern data PD2 and a status read operation SR for transmitting the second pass/fail value PF2. In this regard, in the fifth interval ITV5, the write operation WRITE of the first memory die 100a and the comparison operation CP and the status read operation SR of the second memory die 100b may be performed in parallel.

In the sixth interval ITV6, the first memory die 100a may perform a comparison operation CP for comparing the first training data TD1_D3 with the first pattern data PD1 and a status read operation SR for transmitting the first pass/fail value PF1. Also, in the sixth interval ITV6, the second memory die 100b may perform a write operation WRITE regarding second training data TD2_D3 corresponding to the third delay value D3. In this regard, in the sixth interval ITV6, the comparison operation CP and the status read operation SR of the first memory die 100a and the write operation WRITE of the second memory die 100b may be performed in parallel.

In the seventh interval ITV7, the first memory die 100a may perform a write operation WRITE regarding first training data TD1_D4 corresponding to a fourth delay value D4. Also, in the seventh interval ITV7, the second memory die 100b may perform a comparison operation CP for comparing the second training data TD2_D3 with the second pattern data PD2 and a status read operation SR for transmitting the second pass/fail value PF2. In this regard, in the seventh interval ITV7, the write operation WRITE of the first memory die 100a and the comparison operation CP and the status read operation SR of the second memory die 100b may be performed in parallel.

In the eighth interval ITV8, the first memory die 100a may perform a comparison operation CP for comparing the first training data TD1_D4 with the first pattern data PD1 and a status read operation SR for transmitting the first pass/fail value PF1. Also, in the eighth interval ITV8, the second memory die 100b may perform a write operation WRITE regarding second training data TD2_D4 corresponding to the fourth delay value D4. In this regard, in the eighth interval ITV8, the comparison operation CP and the status read operation SR of the first memory die 100a and the write operation WRITE of the second memory die 100b may be performed in parallel.

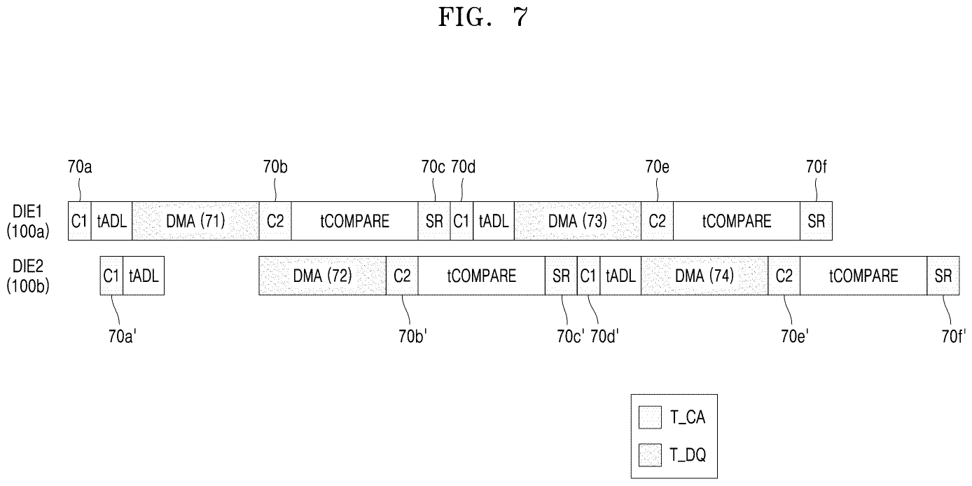

FIG. 7 is a timing diagram illustrating an example of a write training operation of the first memory die 100a and the second memory die 100b of FIG. 5, according to one or more embodiments.

Referring to FIGS. 5 and 7 together, a write training operation may include first transmitting operations T_CA via lines for the command/address signal CA and command/address pins P13 and second transmitting operations T_DQ via lines for the data signal DQ and data pins P11. By performing the first transmitting operations T_CA for the first memory die 100a and the second memory die 100b in an interleaving manner, an idle time for the lines for the command/address signal CA may be reduced. Also, by performing the second transmitting operations T_DQ for the first memory die 100a and the second memory die 100b in an interleaving manner, the idle time for the lines for the data signal DQ may be reduced. Therefore, the write training time for the first memory die 100a and the second memory die 100b may be reduced. Hereinafter, detailed operations for the first memory die 100a and the second memory die 100b will be described.

The first memory die 100a may perform a receiving operation 70a for receiving a first command C1. After a data loading time tADL, a write operation or direct memory access (DMA) 71 may be performed to transmit the first training data TD1 (e.g., the first training data TD1 corresponding to the first delay value) from the controller 20a to the first memory die 100a. Next, the first memory die 100a may perform a receiving operation 70b for receiving a second command C2 and perform a comparison operation between the first training data TD1 and the first pattern data PD1 during a comparison time tCOMPARE. Next, the first memory die 100a may receive a status read command and perform a status read operation SR 70c to transmit the first pass/fail value PF1 in response to the status read command.

Next, the first memory die 100a may perform a receiving operation 70d for receiving the first command C1. After the data loading time tADL, a write operation or DMA 73 may be performed to transmit the first training data TD1 (e.g., the first training data TD1 corresponding to the second delay value) from the controller 20a to the first memory die 100a. Next, the first memory die 100a may perform a receiving operation 70e for receiving the second command C2 and perform a comparison operation between the first training data TD1 and the first pattern data PD1 during the comparison time tCOMPARE. Next, the first memory die 100a may receive a status read command and perform a status read operation SR 70f to transmit the first pass/fail value PF1 in response to the status read command.

The second memory die 100b may perform a receiving operation 70a′ for receiving the first command C1. Here, the receiving operation 70a′ may be performed after the receiving operation 70a, e.g., immediately after the receiving operation 70a. After the data loading time tADL, a write operation or DMA 72 may be performed to transmit the second training data TD2 (e.g., the second training data TD2 corresponding to the first delay value) from the controller 20a to the second memory die 100b. At this time, the DMA 72 may be performed after the DMA 71, e.g., immediately after the DMA 71. Next, the second memory die 100b may perform a receiving operation 70b′ for receiving the second command C2 and perform a comparison operation between the second training data TD2 and the second pattern data PD2 during the comparison time tCOMPARE. Next, the second memory die 100b may receive a status read command and perform a status read operation SR 70c′ to transmit the second pass/fail value PF2 in response to the status read command.

Next, the second memory die 100b may perform a receiving operation 70d′ for receiving the first command C1. After the data loading time tADL, a write operation or DMA 74 may be performed to transmit the second training data TD2 (e.g., the second training data TD2 corresponding to the second delay value) from the controller 20a to the second memory die 100b. At this time, the DMA 74 may be performed after the DMA 73, e.g., immediately after the DMA 73. Next, the second memory die 100b may perform a receiving operation 70e′ for receiving the second command C2 and perform a comparison operation between the second training data TD2 and the second pattern data PD2 during the comparison time tCOMPARE. Next, the second memory die 100b may receive a status read command and perform a status read operation SR 70f′ to transmit the second pass/fail value PF2 in response to the status read command.

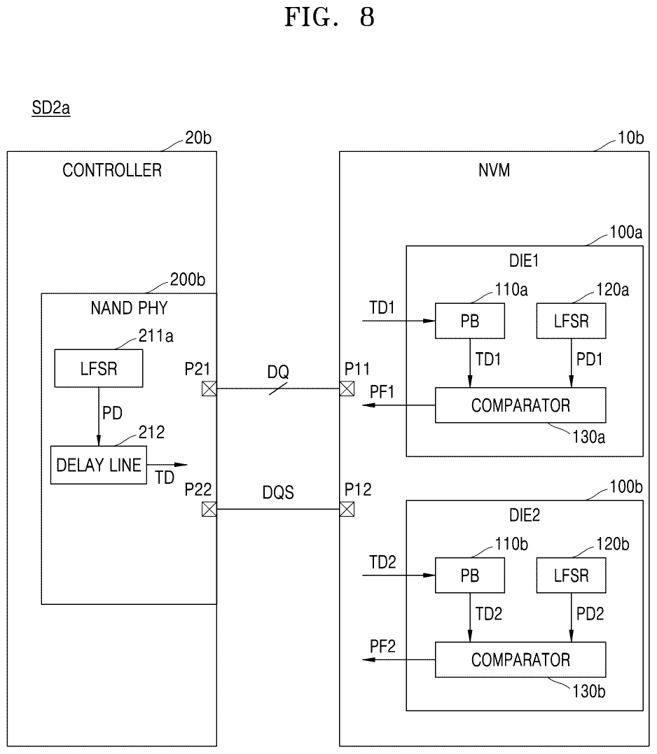

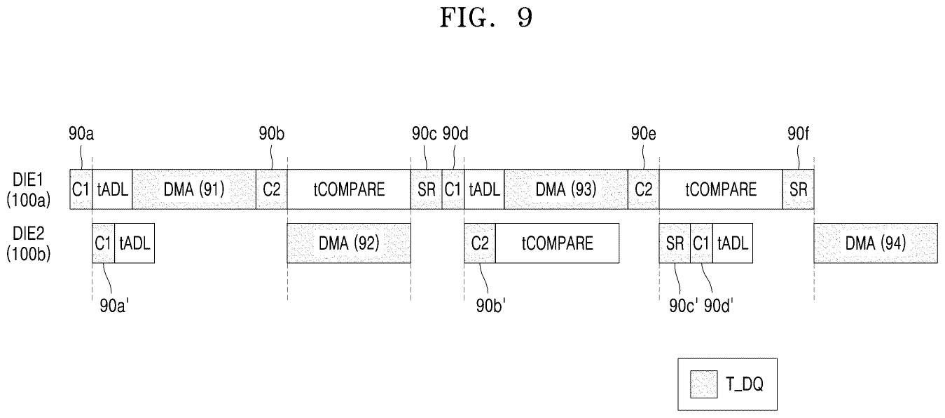

FIG. 8 is a block diagram showing a storage device SD2a according to one or more embodiments. FIG. 9 is a timing diagram illustrating a write training operation of the first memory die 100a and the second memory die 100b of FIG. 8, according to one or more embodiments.

Referring to FIGS. 8 and 9 together, the storage device SD2a may include the non-volatile memory 10b and the controller 20b. The storage device SD2a may correspond to a modified example of the storage device SD2 of FIG. 4, and descriptions given above with reference to FIGS. 1, 2, and 4 may also be applied to the present embodiment. The non-volatile memory 10b may be a DDP including the first memory die 100a and the second memory die 100b. The write training operation may include the second transmitting operations T_DQ via lines for the data signal DQ and the pins P11. By performing the second transmitting operations T_DQ for the first memory die 100a and the second memory die 100b in an interleaving manner, the idle time for the lines for the data signal DQ may be reduced. Therefore, the write training time for the first memory die 100a and the second memory die 100b may be reduced. Hereinafter, detailed operations for the first memory die 100a and the second memory die 100b will be described.

The first memory die 100a may perform a receiving operation 90a for receiving the first command C1 through the pins P11. After the data loading time tADL, a write operation or DMA 91 for transmitting the first training data TD1 corresponding to a first delay value from the controller 20b to the first memory die 100a via the pins P11 may be performed. Next, the first memory die 100a may perform a receiving operation 90b for receiving the second command C2 through the pins P11 and perform a comparison operation between the first training data TD1 and the first pattern data PD1 during a comparison time tCOMPARE. Next, the first memory die 100a may receive a status read command through the pins P11 and perform a status read operation SR 90c to transmit the first pass/fail value PF1 in response to the status read command. At this time, a status read operation 90c may be performed after a DMA 92 of the second memory die 100b, e.g., immediately after the DMA 92.

Next, the first memory die 100a may perform a receiving operation 90d for receiving the first command C1 through the pins P11. After the data loading time tADL, a write operation or DMA 93 for transmitting the first training data TD1 corresponding to a second delay value from the controller 20a to the first memory die 100a via the pins P11 may be performed. Next, the first memory die 100a may perform a receiving operation 90e for receiving the second command C2 and perform a comparison operation between the first training data TD1 and the first pattern data PD1 during the comparison time tCOMPARE.

Next, the first memory die 100a may receive a status read command through the pins P11 and perform a status read operation SR 90f to transmit the first pass/fail value PF1 in response to the status read command.

The second memory die 100b may perform a receiving operation 90a′ for receiving the first command C1 through the pins P11. Here, the receiving operation 90a′ may be performed after the receiving operation 90a, e.g., immediately after the receiving operation 90a. After the data loading time tADL, a write operation or DMA 92 for transmitting the second training data TD2 corresponding to a first delay value from the controller 20a to the second memory die 100b via the pins P11 may be performed. At this time, the DMA 92 may be performed after the receiving operation 90b of the first memory die 100a, e.g., immediately after the receiving operation 90b.

Next, the second memory die 100b may perform a receiving operation 90b′ for receiving the second command C2 through the pins P11 and perform a comparison operation between the second training data TD2 and the second pattern data PD2 during the comparison time tCOMPARE. At this time, the receiving operation 90b′ may be performed after the receiving operation 90d of the first memory die 100a, e.g., immediately after the receiving operation 90d. Next, the second memory die 100b may receive a status read command through the pins P11 and perform a status read operation SR 90c′ to transmit the second pass/fail value PF2 in response to the status read command. At this time, the status read operation 90c′ may be performed after the receiving operation 90e of the first memory die 100a, e.g., immediately after the receiving operation 90e.

Next, the second memory die 100b may perform a receiving operation 90d′ for receiving the first command C1 through the pins P11. After the data loading time tADL, a write operation or DMA 94 for transmitting the second training data TD2 corresponding to a second delay value from the controller 20a to the second memory die 100b via the pins P11 may be performed. For example, the DMA 94 may be performed after a status read operation 90f of the first memory die 100a, e.g., immediately after the status read operation 90f.

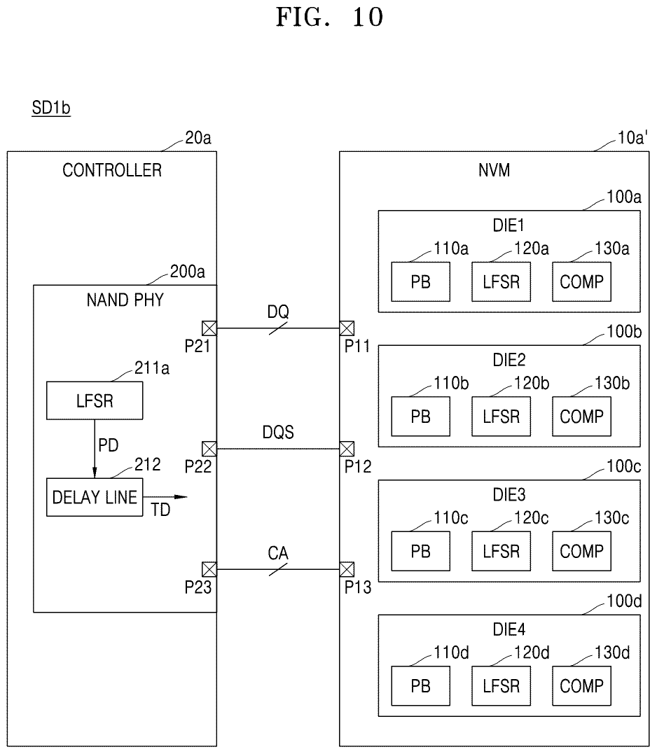

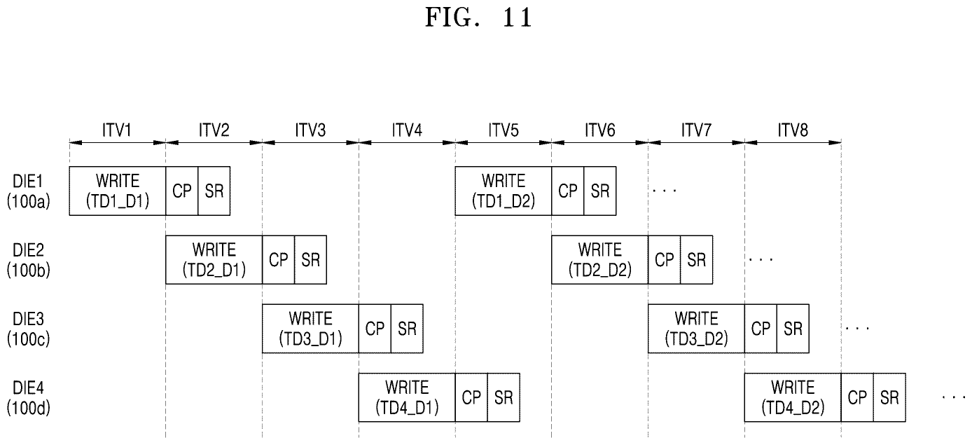

FIG. 10 is a block diagram showing a storage device SD1b according to one or more embodiments. FIG. 11 is a timing diagram illustrating a write training operation of the first to fourth memory dies 100a to 100d of FIG. 10, according to one or more embodiments.

Referring to FIGS. 10 and 11 together, the storage device SD1b may include a non-volatile memory 10a′ and the controller 20a. The storage device SD1b may correspond to a modified example of the storage device SD1 of FIG. 3, and descriptions given above with reference to FIGS. 1 to 3 may also be applied to the present embodiment. The non-volatile memory 10a′ may be a QDP including first to fourth memory dies 100a to 100d. The non-volatile memory 10a′ may correspond to a modified example of the non-volatile memory 10a of FIG. 5, and descriptions given above with reference to FIGS. 5 and 6 may also be applied to the present embodiment.

A write training operation may be performed during a write training interval including the first to eighth intervals ITV1 to ITV8. In the first interval ITV1, the first memory die 100a may perform a write operation WRITE regarding first training data TD1_D1 corresponding to the first delay value D1. In the second interval ITV2, the first memory die 100a may perform a comparison operation CP for comparing the first training data TD1_D1 with the first pattern data PD1, and subsequently perform a status read operation SR for transmitting the first pass/fail value PF1 to the controller 20a. In the second interval ITV2, the second memory die 100b may perform a write operation WRITE regarding second training data TD2_D1 corresponding to the first delay value D1. In this regard, in the second interval ITV2, the comparison operation CP and the status read operation SR of the first memory die 100a and the write operation WRITE of the second memory die 100b may be performed in parallel.

In the third interval ITV3, the second memory die 100b may perform a comparison operation CP for comparing the second training data TD2_D1 with the second pattern data PD2 and, subsequently, a status read operation SR for transmitting the second pass/fail value PF2 to the controller 20a. In the third interval ITV3, a third memory die 100c may perform a write operation WRITE regarding third training data TD3_D1 corresponding to the first delay value D1. In this regard, in the third interval ITV3, the comparison operation CP and the status read operation SR of the second memory die 100b and the write operation WRITE of the third memory die 100c may be performed in parallel.

In the fourth interval ITV4, the third memory die 100c may perform a comparison operation CP for comparing the third training data TD3_D1 with third pattern data PD3 and, subsequently, a status read operation SR for transmitting a third pass/fail value PF3 to the controller 20a. In the fourth interval ITV4, a fourth memory die 100d may perform a write operation WRITE regarding fourth training data TD4_D1 corresponding to the first delay value D1. In this regard, in the fourth interval ITV4, the comparison operation CP and the status read operation SR of the third memory die 100c and the write operation WRITE of the fourth memory die 100d may be performed in parallel.

In the fifth interval ITV5, the fourth memory die 100d may perform a comparison operation CP for comparing the fourth training data TD4_D1 with fourth pattern data PD4 and, subsequently, a status read operation SR for transmitting a fourth pass/fail value PF4 to the controller 20a. In the fifth interval ITV5, the first memory die 100a may perform a write operation WRITE regarding first training data TD1_D2 corresponding to the second delay value D2. In this regard, in the fifth interval ITV5, the comparison operation CP and the status read operation SR of the fourth memory die 100d and the write operation WRITE of the first memory die 100a may be performed in parallel.

In the sixth interval ITV6, the first memory die 100a may perform a comparison operation CP for comparing the first training data TD1_D2 with the first pattern data PD1, and subsequently perform a status read operation SR for transmitting the first pass/fail value PF1 to the controller 20a. In the sixth interval ITV6, the second memory die 100b may perform a write operation WRITE regarding second training data TD2_D2 corresponding to the second delay value D2. In this regard, in the sixth interval ITV6, the comparison operation CP and the status read operation SR of the first memory die 100a and the write operation WRITE of the second memory die 100b may be performed in parallel.

In the seventh interval ITV7, the second memory die 100b may perform a comparison operation CP for comparing the second training data TD2_D2 with the second pattern data PD2 and, subsequently, a status read operation SR for transmitting the second pass/fail value PF2 to the controller 20a. In the seventh interval ITV7, the third memory die 100c may perform a write operation WRITE regarding third training data TD3_D2 corresponding to the second delay value D2. In this regard, in the seventh interval ITV7, the comparison operation CP and the status read operation SR of the second memory die 100b and the write operation WRITE of third memory die 100c may be performed in parallel.

In the eighth interval ITV8, the third memory die 100c may perform a comparison operation CP for comparing the third training data TD3_D2 with third pattern data PD3 and, subsequently, a status read operation SR for transmitting the third pass/fail value PF3 to the controller 20a. In the eighth interval ITV8, the fourth memory die 100d may perform a write operation WRITE regarding fourth training data TD4_D2 corresponding to the second delay value D2. In this regard, in eighth interval ITV8, the comparison operation CP and the status read operation SR of the third memory die 100c and the write operation WRITE of the fourth memory die 100d may be performed in parallel.

According to the present embodiment, a compare operation CP and a status read operation SR of one of the first to fourth memory dies 100a to 100d and a write operation WRITE of another one of the first to fourth memory dies 100a to 100d may be performed in parallel. While a compare operation CP and a status read operation SR are being performed on one of the first to fourth memory dies 100a to 100d, training data may be transmitted to another one of the first to fourth memory dies 100a to 100d through lines for the data signal DQ of the first channel CH1, and thus the idle time of the line for the data signal DQ of the first channel CH1 may be reduced. By performing write training in this interleaving manner, the write training operation time may be reduced.

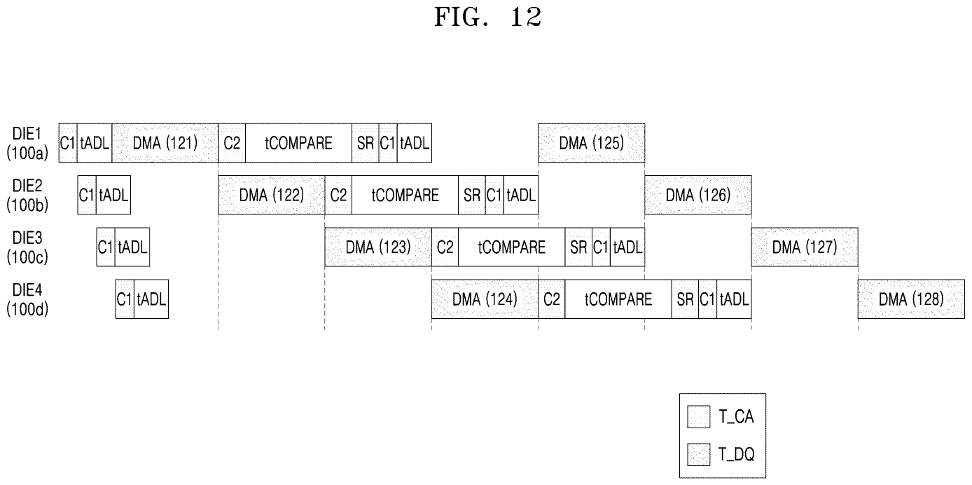

FIG. 12 is a timing diagram illustrating an example of a write training operation of the first to fourth memory dies 100a to 100d of FIG. 10, according to one or more embodiments.

Referring to FIGS. 10 and 12 together, a write training operation may include the first transmitting operations T_CA via lines for the command/address signal CA and command/address pins P13 and the second transmitting operations T_DQ via lines for the data signal DQ and the data pins P11. By performing the first transmitting operations T_CA for the first to fourth memory dies 100a to 100d in an interleaving manner, the idle time for the lines for the command/address signal CA may be reduced. Also, by performing the second transmitting operations T_DQ for the first to fourth memory dies 100a to 100d in an interleaving manner, the idle time for the lines for the data signal DQ may be reduced. Therefore, the write training time for the first to fourth memory dies 100a to 100d may be reduced. Hereinafter, detailed operations for the first to fourth memory dies 100a to 100d will be described.

The first memory die 100a may receive the first command C1 and, after the data loading time tADL, perform a write operation or DMA 121 for receiving the first training data TD1 (e.g., the first training data TD1 corresponding to the first delay value) from the controller 20a. Next, the first memory die 100a may receive the second command C2 and perform a comparison operation between the first training data TD1 and the first pattern data PD1 during the comparison time tCOMPARE. Next, the first memory die 100a may receive a status read command and perform a status read operation SR to transmit the first pass/fail value PF1 in response to the status read command. Next, the first memory die 100a may receive the first command C1 and, after the data loading time tADL, perform a write operation or DMA 125 for receiving the first training data TD1 (e.g., the first training data TD1 corresponding to the second delay value) from the controller 20a.

The second memory die 100b may receive the first command C1 and, after the data loading time tADL, perform a write operation or DMA 122 for receiving the second training data TD2 (e.g., the second training data TD2 corresponding to the first delay value) from the controller 20a. At this time, the DMA 122 may be performed after the DMA 121, e.g., immediately after the DMA 121. Next, the second memory die 100b may receive the second command C2 and perform a comparison operation between the second training data TD2 and the second pattern data PD2 during the comparison time tCOMPARE. Next, the second memory die 100b may receive a status read command and perform a status read operation SR to transmit the second pass/fail value PF2 in response to the status read command. Next, the second memory die 100b may receive the first command C1 and, after the data loading time tADL, perform a write operation or DMA 126 for receiving the second training data TD2 (e.g., the second training data TD2 corresponding to the second delay value) from the controller 20a. At this time, the DMA 126 may be performed after the DMA 125, e.g., immediately after the DMA 125.

The third memory die 100c may receive the first command C1 and, after the data loading time tADL, perform a write operation or DMA 123 for receiving third training data TD3 (e.g., third training data TD3 corresponding to the first delay value) from the controller 20a. At this time, the DMA 123 may be performed after the DMA 122, e.g., immediately after the DMA 122. Next, the third memory die 100c may receive the second command C2 and perform a comparison operation between the third training data TD3 and the third pattern data PD3 during the comparison time tCOMPARE. Next, the third memory die 100c may receive a status read command and perform a status read operation SR to transmit the third pass/fail value PF3 in response to the status read command. Next, the third memory die 100c may receive the first command C1 and, after the data loading time tADL, perform a write operation or DMA 127 for receiving third training data TD3 (e.g., third training data TD3 corresponding to the second delay value) from the controller 20a. At this time, the DMA 127 may be performed after the DMA 126, e.g., immediately after the DMA 126.

The fourth memory die 100d may receive the first command C1 and, after the data loading time tADL, perform a write operation or DMA 124 for receiving fourth training data TD4 (e.g., fourth training data TD4 corresponding to the first delay value) from the controller 20a. At this time, the DMA 124 may be performed after the DMA 123, e.g., immediately after the DMA 123. Next, the fourth memory die 100d may receive the second command C2 and perform a comparison operation between the fourth training data TD4 and fourth pattern data PD4 during the comparison time tCOMPARE. Next, the fourth memory die 100d may receive a status read command and perform a status read operation SR to transmit the fourth pass/fail value PF4 in response to the status read command. Next, the fourth memory die 100d may receive the first command C1 and, after the data loading time tADL, perform a write operation or DMA 128 for receiving fourth training data TD4 (e.g., fourth training data TD4 corresponding to the second delay value) from the controller 20a. At this time, the DMA 128 may be performed after the DMA 127, e.g., immediately after the DMA 127.

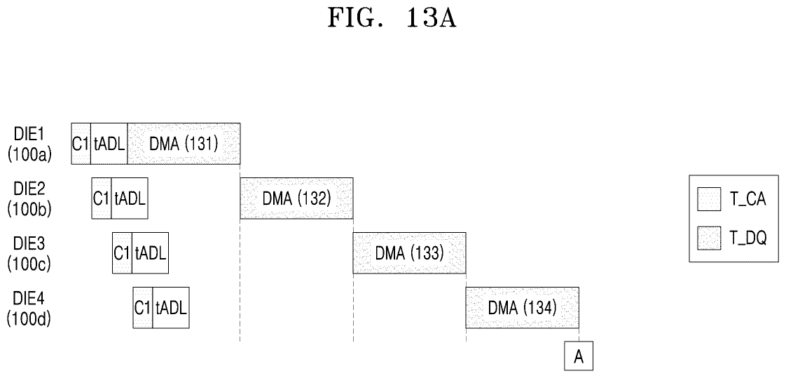

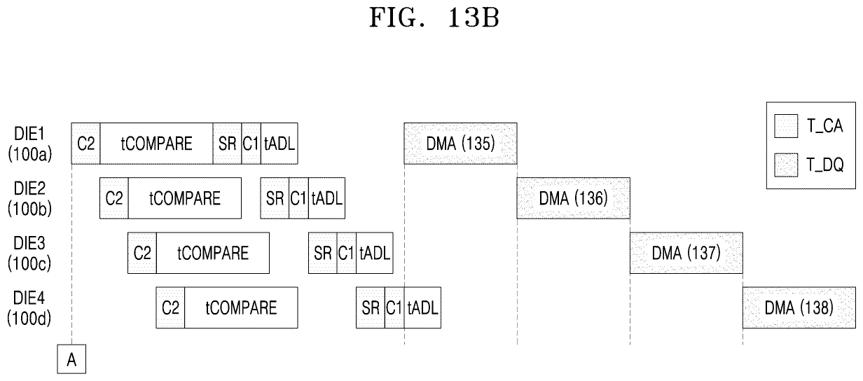

FIGS. 13A and 13B are timing diagrams illustrating another example of a write training operation of the first to fourth memory dies 100a to 100d of FIG. 10, according to one or more embodiments.

Referring to FIGS. 10, 13A, and 13B together, a write training operation may include the first transmitting operations T_CA via lines for the command/address signal CA and command/address pins P13 and the second transmitting operations T_DQ via lines for the data signal DQ and the data pins P11. The present embodiment may correspond to a modified example of FIG. 12, and redundant descriptions will be omitted.

According to the present embodiment, operations for transmitting the first command C1 with respect to the first to fourth memory dies 100a to 100d may be sequentially performed through lines for the command/address signal CA, and operations (e.g., write operation or DMA) 131 to 134 for transmitting first to fourth training data TD1 to TD4 corresponding to the first delay value may also be sequentially performed through lines for the data signal DQ. When the transmission of the first to fourth training data TD1 to TD4 corresponding to the first delay value is completed, operations for transmitting the second command C2 with respect to the first to fourth memory dies 100a to 100d may be sequentially performed.

The first to fourth memory dies 100a to 100d may perform comparison operations in parallel during the comparison time tCOMPARE, and status read operations SR regarding the first to fourth memory dies 100a to 100d may be performed sequentially via the lines for the command/address signal CA. Next, operations for transmitting the first command C1 with respect to the first to fourth memory dies 100a to 100d may be sequentially performed through lines for the command/address signal CA, and operations (e.g., write operation or DMA) 135 to 138 for transmitting first to fourth training data TD1 to TD4 corresponding to the second delay value may also be sequentially performed through lines for the data signal DQ. The above-stated process may be repeated with respect to different delay values.

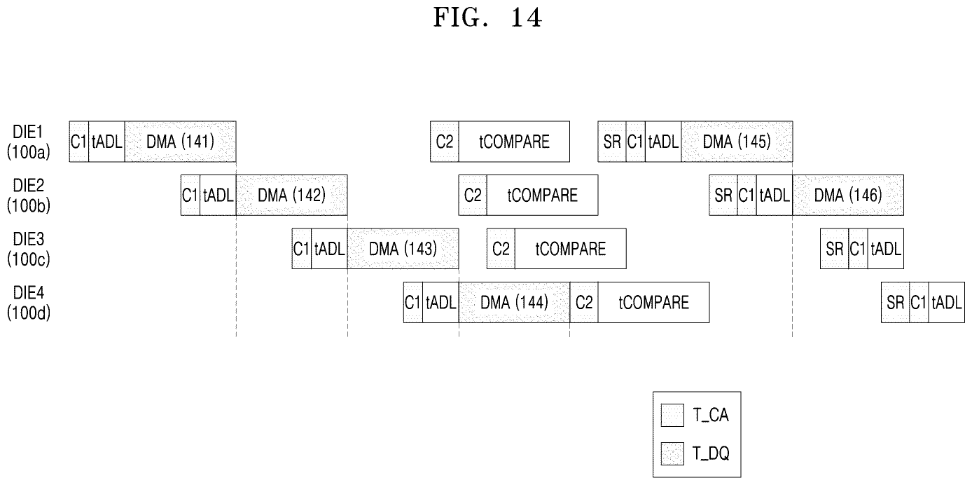

FIG. 14 is a timing diagram illustrating another example of a write training operation of the first to fourth memory dies 100a to 100d of FIG. 10, according to one or more embodiments.

Referring to FIGS. 10 and 14 together, a write training operation may include the first transmitting operations T_CA via lines for the command/address signal CA and command/address pins P13 and the second transmitting operations T_DQ via lines for the data signal DQ and the data pins P11. The present embodiment may correspond to a modified example of the writing training operation of FIGS. 12, 13A, and 13B, and thus descriptions given above with reference to FIGS. 12-13B may also be applied to the present embodiment.

According to the present embodiment, write training for the first to fourth memory dies 100a to 100d may be performed by using a set feature command and a get feature command. Operations for transmitting the first command C1 with respect to the first to fourth memory dies 100a to 100d may be sequentially performed via lines for the command/address signal CA. A DMA 141 of the first memory die 100a, a DMA 142 of the second memory die 100b, a DMA 143 of the third memory die 100c, and a DMA 144 of the fourth memory die 100d may be sequentially performed through lines for the data signal DQ.

Operations for transmitting the second command C2 with respect to the first to fourth memory dies 100a to 100d may be sequentially performed via lines for the command/address signal CA. For example, an operation for transmitting the second command C2 with respect to the first memory die 100a may be performed after an operation for transmitting the first command C1 with respect to the fourth memory die 100d. For example, the comparison operation of the first memory die 100a may be performed in parallel with the DMA 144 of the fourth memory die 100d, thereby reducing the write training operation time.

Also, status read operations SR with respect to the first to fourth memory dies 100a to 100d may be sequentially performed via lines for the command/address signal CA. For example, the status read operation SR with respect to the first memory die 100a may be performed after an operation for transmitting the second command C2 with respect to the fourth memory die 100d. For example, the status read operation SR with respect to the first memory die 100a may be performed in parallel with the comparison operation of the fourth memory die 100d, thereby reducing the write training operation time.

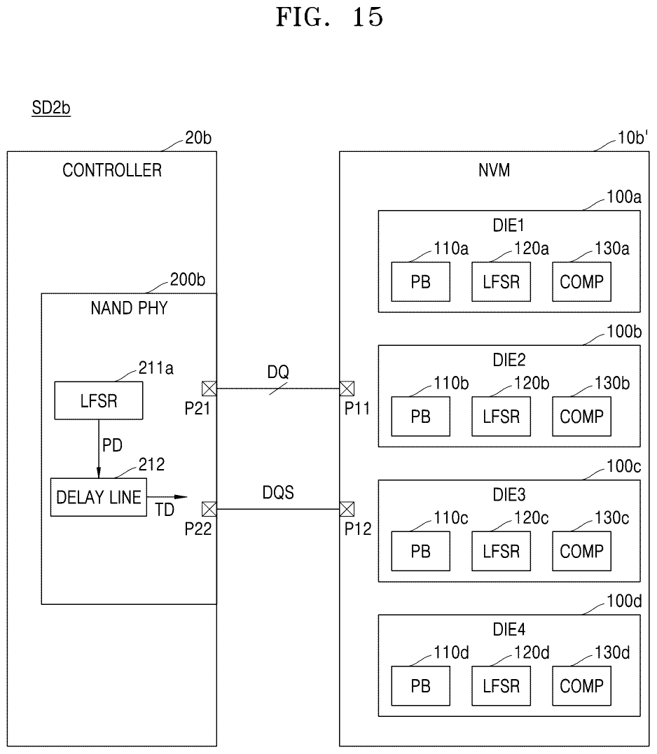

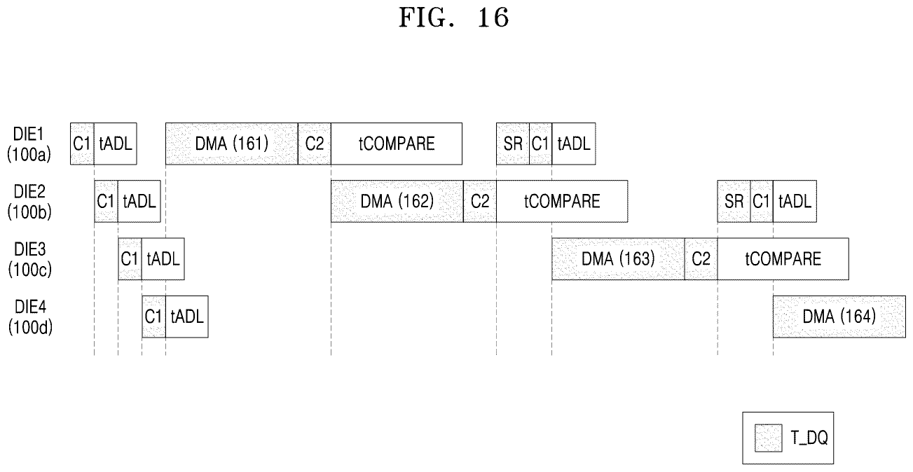

FIG. 15 is a block diagram showing a storage device SD2b according to one or more embodiments. FIG. 16 is a timing diagram illustrating an example of a write training operation of first to fourth memory dies 100a to 100d of FIG. 15, according to one or more embodiments.

Referring to FIGS. 15 and 16 together, the storage device SD2b may include a non-volatile memory 10b′ and the controller 20b. The storage device SD2b may correspond to a modified example of the storage device SD2 of FIG. 4, and descriptions given above with reference to FIGS. 1, 2, and 4 may also be applied to the present embodiment. The non-volatile memory 10b′ may be a QDP including first to fourth memory dies 100a to 100d. The write training operation may include the second transmitting operations T_DQ via lines for the data signal DQ and the pins P11. By performing the second transmitting operations T_DQ for the first to fourth memory dies 100a to 100d in an interleaving manner, the idle time for the lines for the data signal DQ may be reduced. Therefore, the write training time for the first to fourth memory dies 100a to 100d may be reduced. Hereinafter, detailed operations for the first to fourth memory dies 100a to 100d will be described.

An operation of the first memory die 100a for receiving the first command C1, an operation of the second memory die 100b for receiving the first command C1, an operation of the third memory die 100c for receiving the first command C1, and an operation of the fourth memory die 100d for receiving the first command C1 may be sequentially performed through lines for the data signal DQ. Next, a DMA 161, an operation of receiving the second command C2, and a comparison operation during the comparison time tCOMPARE of the first memory die 100a may be sequentially performed. During the comparison time tCOMPARE of the first memory die 100a, the second memory die 100b may perform a DMA 162 for receiving the second training data TD2 through the lines for the data signal DQ. Next, an operation of receiving the second command C2 and a comparison operation during the comparison time tCOMPARE of the second memory die 100b may be sequentially performed.

During the comparison time tCOMPARE of the second memory die 100b, the first memory die 100a may receive a status read command through the lines for the data signal DQ, perform the status read operation SR to transmit the first pass/fail value PF1, and then receive the first command C1 through the lines for the data signal DQ. Also, during the comparison time tCOMPARE of the second memory die 100b, the third memory die 100c may perform a DMA 163 for receiving the third training data TD3 through the lines for the data signal DQ. Next, an operation of receiving the second command C2 and a comparison operation during the comparison time tCOMPARE of the third memory die 100c may be sequentially performed.

During the comparison time tCOMPARE of the third memory die 100c, the second memory die 100b may receive a status read command through the lines for the data signal DQ, perform the status read operation SR to transmit the second pass/fail value PF2, and then receive the first command C1 through the lines for the data signal DQ. Also, during the comparison time tCOMPARE of the third memory die 100c, the fourth memory die 100d may perform a DMA 164 for receiving the fourth training data TD4 through the lines for the data signal DQ.

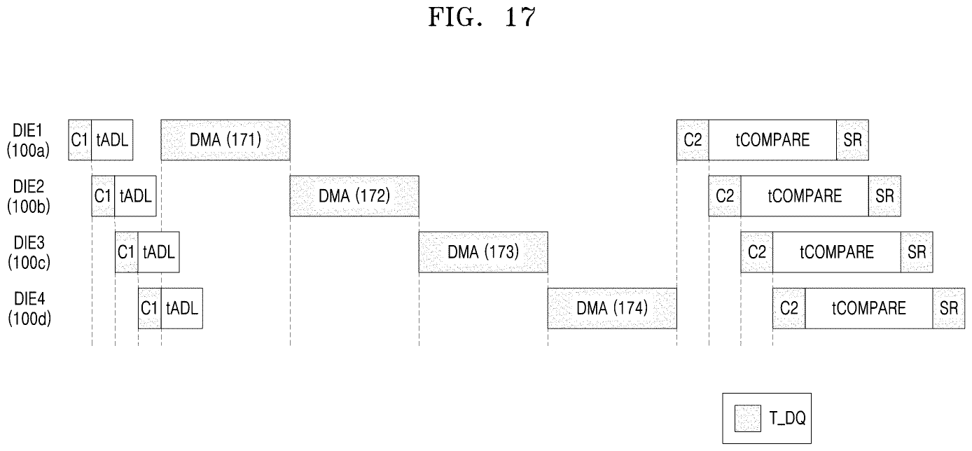

FIG. 17 is a timing diagram illustrating another example of a write training operation of first to fourth memory dies 100a to 100d of FIG. 15, according to one or more embodiments.

Referring to FIGS. 15 and 17 together, a write training operation may include the second transmitting operations T_DQ via the lines for the data signal DQ and the data pins P11. The present embodiment may correspond to a modified example of the writing training operation of FIG. 16, and thus descriptions given above with reference to FIGS. 15 and 16 may also be applied to the present embodiment.

According to the present embodiment, write training for the first to fourth memory dies 100a to 100d may be performed by using a set feature command and a get feature command. Operations for receiving the first command C1 from the first to fourth memory dies 100a to 100d may be sequentially performed via the lines for the data signal DQ. Next, DMAs 171 to 174 of the first to fourth memory dies 100a to 100d may be sequentially performed via the lines for the data signal DQ.

Next, operations for receiving the second command C2 from the first to fourth memory dies 100a to 100d may be sequentially performed via the lines for the data signal DQ. For example, an operation for receiving the second command C2 from the first memory die 100a may be performed after the DMA 174 of the fourth memory die 100d. For example, the comparison operation of the first memory die 100a may be performed in parallel with an operation of the second memory die 100b for receiving the second command C2, thereby reducing the write training operation time.

Next, the status read operations SR with respect to the first to fourth memory dies 100a to 100d may be sequentially performed via the lines for the data signal DQ. For example, the status read operation SR of the first memory die 100a may be performed in parallel with a comparison operation of the second memory die 100b, and the status read operation SR of the second memory die 100b may be performed in parallel with a comparison operation of the third memory die 100c, thereby reducing the write training operation time.

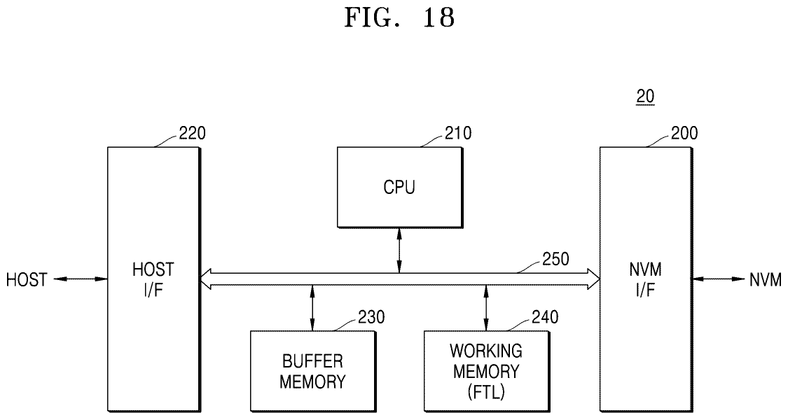

FIG. 18 is a block diagram showing the controller 20 according to one or more embodiments.

Referring to FIG. 1 and FIG. 18 together, the controller 20 may include a central processing unit (CPU) 210, a host interface 220, a buffer memory 230, a working memory 240, and a non-volatile memory interface 200, which may communicate with one another via a bus 250. According to some embodiments, the controller 20 may further include a packet manager, an error correction code (ECC) engine, and/or an advanced encryption standard (AES) engine.

The host interface 220 may transmit and receive packets to and from a host. A packet transmitted from a host to the host interface 220 may include a command or data to be programmed to the NVM 120, and a packet transmitted from the host interface 220 to the host may include a response to the command or data read from the non-volatile memory 10.

The non-volatile memory interface 200 may transmit data to be programmed to the non-volatile memory 10 to the non-volatile memory 10 and/or receive data read from the non-volatile memory 10. The non-volatile memory interface 200 may be implemented to comply with a standard protocol such as a Toggle standard or an Open NAND Flash Interface (ONFI) standard.

A flash translation layer FTL may be loaded to the working memory 240, and data program and/or read operations for a non-volatile memory may be controlled by the CPU 210 executing the flash translation layer FTL. The flash translation layer FTL may perform various functions such as address mapping, wear-leveling, and/or garbage collection.

According to the present embodiment, the CPU 210 may control an overall write training operation. For example, the CPU 210 may control the pattern generator 211 and the delay line 212 to generate training data and a data strobe signal including a training pattern for write training. For example, the pattern generator 211 and the delay line 212 may be included in the non-volatile memory interface 200. For example, a NAND PHY 200a of FIG. 3 and a NAND PHY 200b of FIG. 4 may correspond to an example of the non-volatile memory interface 200.

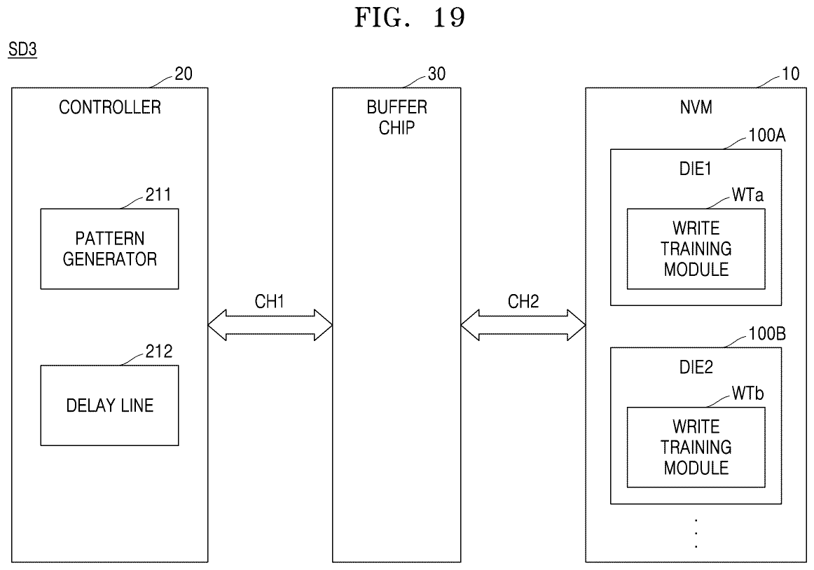

FIG. 19 is a block diagram showing a storage device SD3 according to one or more embodiments.

Referring to FIG. 19, the storage device SD3 may include the non-volatile memory 10, the controller 20, and a buffer chip 30. The buffer chip 30 may communicate with the controller 20 through a first channel CH1, and the non-volatile memory 10 may communicate with the buffer chip 30 through a second channel CH2. The buffer chip 30 may be connected between the controller 20 and the non-volatile memory 10 and may also be referred to as a frequency boosting interface (FBI) circuit. For example, the non-volatile memory 10 and the buffer chip 30 may be implemented in a single package. The storage device SD3 may correspond to a modified example of the storage device SD of FIG. 1 and may further include the buffer chip 30 as compared to the storage device SD. Descriptions given above with reference to FIGS. 1 to 18 may be applied to the present embodiment.

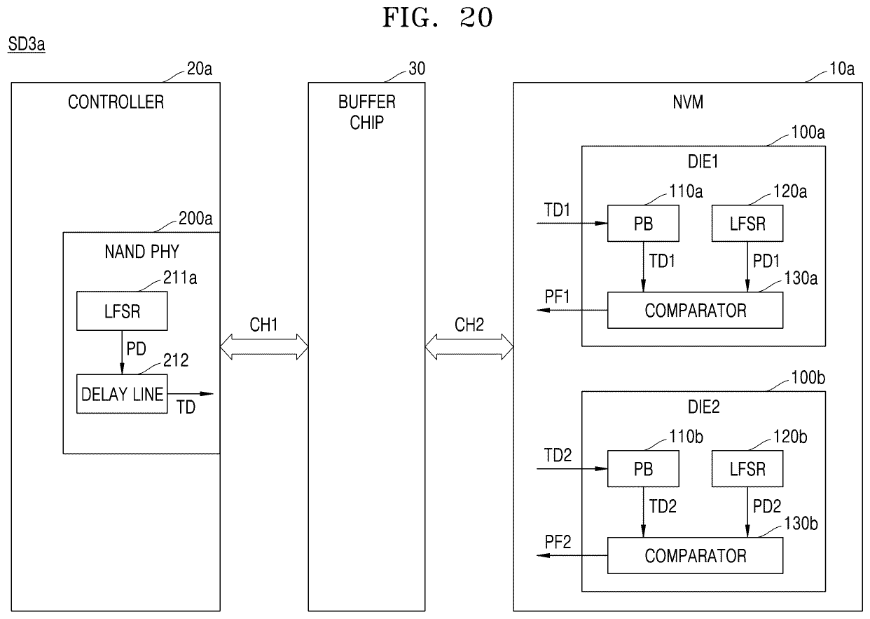

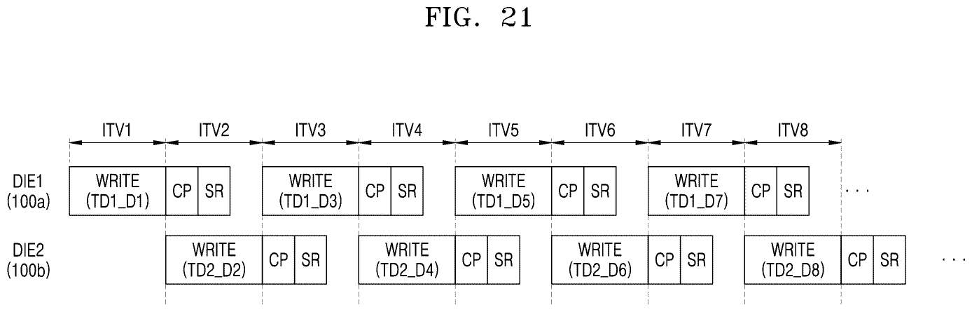

FIG. 20 is a block diagram showing a storage device SD3a according to one or more embodiments. FIG. 21 is a timing diagram illustrating a write training operation of the first memory die 100a and the second memory die 100b of FIG. 20, according to one or more embodiments.

Referring to FIGS. 20 and 21 together, the storage device SD3a may include the non-volatile memory 10a, the controller 20a, and the buffer chip 30. The storage device SD3a may correspond to a modified example of the storage device SD3 of FIG. 19. The non-volatile memory 10a may be a DDP including the first memory die 100a and the second memory die 100b.

When the storage device SD3a includes the buffer chip 30, a write training operation may include a first write training operation between the controller 20a and the buffer chip 30 and a second write training operation between the buffer chip 30 and the non-volatile memory 10a. At this time, the second writing training operation may be performed similarly as those of the embodiments described above with reference to FIGS. 1 to 18.

Hereinafter, descriptions will be given based on the first write training operation.

The first write training operation may be performed during a first write training interval including a first interval ITV1 to an eighth interval ITV8. In the first interval ITV1, the first memory die 100a may perform a write operation WRITE regarding first training data TD1_D1 corresponding to the first delay value D1. In detail, the first memory die 100a may receive a first command and an address instructing a program operation from the controller 20a, subsequently receive the first training data TD1_D1 from the controller 20a through the buffer chip 30, and store the received first training data TD1_D1 in the page buffer 110a. For example, the first training data TD1_D1 may correspond to a training pattern having a delay corresponding to the first delay value D1 of a DLL or a phased locked loop relative to the data strobe signal DQS.

In the second interval ITV2, the first memory die 100a may perform a comparison operation CP for comparing the first training data TD1_D1 with the first pattern data PD1, and subsequently perform a status read operation SR for transmitting the first pass/fail value PF1 to the controller 20a through the buffer chip 30. In detail, the first memory die 100a may receive a second command instructing a comparison operation. In response to a received second command, the LFSR 120a may generate the first pattern data PD1, and the comparator 130a may generate the first pass/fail value PF1 by comparing the first training data TD1_D1 with the first pattern data PD1. Also, the first memory die 100a may receive a third command requesting the first pass/fail value PF1 and transmit the first pass/fail value PF1 to the controller 20a through the buffer chip 30 in response to a received third command.

In the second interval ITV2, the second memory die 100b may perform a write operation WRITE regarding second training data TD2_D2 corresponding to the second delay value D2, received from the controller 20a through the buffer chip 30. For example, the second training data TD2_D2 may correspond to a training pattern having a delay corresponding to the second delay value D2 of a DLL relative to the data strobe signal DQS. For example, the second delay value D2 may be greater than the first delay value D1. In detail, the second memory die 100b may receive a first command and an address instructing a program operation from the controller 20a, subsequently receive the second training data TD2_D2 from the controller 20a through the buffer chip 30, and store the received second training data TD2_D2 in the page buffer 110b. In this regard, in the second interval ITV2, the comparison operation CP and the status read operation SR of the first memory die 100a and the write operation WRITE of the second memory die 100b may be performed in parallel.

In the third interval ITV3, the first memory die 100a may perform a write operation WRITE regarding first training data TD1_D3 corresponding to the third delay value D3, received from the controller 20a through the buffer chip 30. For example, the first training data TD1_D3 may correspond to a training pattern having a delay corresponding to the third delay value D3 of a DLL relative to the data strobe signal DQS. For example, the third delay value D3 may be greater than the second delay value D2. Also, in the third interval ITV3, the second memory die 100b may perform a comparison operation CP for comparing the second training data TD2_D2 with the second pattern data PD2 and a status read operation SR for transmitting the second pass/fail value PF2 to the controller 20a through the buffer chip 30. In this regard, in the third interval ITV3, the write operation WRITE of the first memory die 100a and the comparison operation CP and the status read operation SR of the second memory die 100b may be performed in parallel.

In the fourth interval ITV4, the first memory die 100a may perform a comparison operation CP for comparing the first training data TD1_D3 with the first pattern data PD1 and a status read operation SR for transmitting the first pass/fail value PF1 to the controller 20a through the buffer chip 30. Also, in the fourth interval ITV4, the second memory die 100b may perform a write operation WRITE regarding second training data TD2_D4 corresponding to the fourth delay value D4, received from the controller 20a through the buffer chip 30. For example, the second training data TD2_D4 may correspond to a training pattern having a delay corresponding to the fourth delay value D4 of a DLL relative to the data strobe signal DQS. For example, the fourth delay value D4 may be greater than the third delay value D3. In this regard, in the fourth interval ITV4, the comparison operation CP and the status read operation SR of the first memory die 100a and the write operation WRITE of the second memory die 100b may be performed in parallel.

In the fifth interval ITV5, the first memory die 100a may perform a write operation WRITE regarding first training data TD1_D5 corresponding to a fifth delay value D5, received from the controller 20a through the buffer chip 30. For example, the first training data TD1_D5 may correspond to a training pattern having a delay corresponding to the fifth delay value D5 of a DLL relative to the data strobe signal DQS. For example, the fifth delay value D5 may be greater than the fourth delay value D4. Also, in the fifth interval ITV5, the second memory die 100b may perform a comparison operation CP for comparing the second training data TD2_D4 with the second pattern data PD2 and a status read operation SR for transmitting the second pass/fail value PF2 to the controller 20a through the buffer chip 30. In this regard, in the fifth interval ITV5, the write operation WRITE of the first memory die 100a and the comparison operation CP and the status read operation SR of the second memory die 100b may be performed in parallel.

In the sixth interval ITV6, the first memory die 100a may perform a comparison operation CP for comparing first training data TD1_D5 with the first pattern data PD1 and a status read operation SR for transmitting the first pass/fail value PF1 to the controller 20a through the buffer chip 30. Also, in the sixth interval ITV6, the second memory die 100b may perform a write operation WRITE regarding second training data TD2_D6 corresponding to a sixth delay value D6, received from the controller 20a through the buffer chip 30. For example, the second training data TD2_D6 may correspond to a training pattern having a delay corresponding to the sixth delay value D6 of a DLL relative to the data strobe signal DQS. For example, the sixth delay value D6 may be greater than the fifth delay value D5. In this regard, in the sixth interval ITV6, the comparison operation CP and the status read operation SR of the first memory die 100a and the write operation WRITE of the second memory die 100b may be performed in parallel.

In the seventh interval ITV7, the first memory die 100a may perform a write operation WRITE regarding first training data TD1_D7 corresponding to a seventh delay value D7, received from the controller 20a through the buffer chip 30. For example, the first training data TD1_D7 may correspond to a training pattern having a delay corresponding to the seventh delay value D7 of a DLL relative to the data strobe signal DQS. For example, the seventh delay value D7 may be greater than the sixth delay value D6. Also, in the seventh interval ITV7, the second memory die 100b may perform a comparison operation CP for comparing the second training data TD2_D6 with the second pattern data PD2 and a status read operation SR for transmitting the second pass/fail value PF2 to the controller 20a through the buffer chip 30. In this regard, in the seventh interval ITV7, the write operation WRITE of the first memory die 100a and the comparison operation CP and the status read operation SR of the second memory die 100b may be performed in parallel.

In the eighth interval ITV8, the first memory die 100a may perform a comparison operation CP for comparing the first training data TD1_D7 with the first pattern data PD1 and a status read operation SR for transmitting the first pass/fail value PF1 to the controller 20a through the buffer chip 30. Also, in the eighth interval ITV8, the second memory die 100b may perform a write operation WRITE regarding second training data TD2_D8 corresponding to an eighth delay value D8, received from the controller 20a through the buffer chip 30. For example, the second training data TD2_D8 may correspond to a training pattern having a delay corresponding to the eighth delay value D8 of a DLL relative to the data strobe signal DQS. For example, the eighth delay value D8 may be greater than the seventh delay value D7. In this regard, in the eighth interval ITV8, the comparison operation CP and the status read operation SR of the first memory die 100a and the write operation WRITE of the second memory die 100b may be performed in parallel.

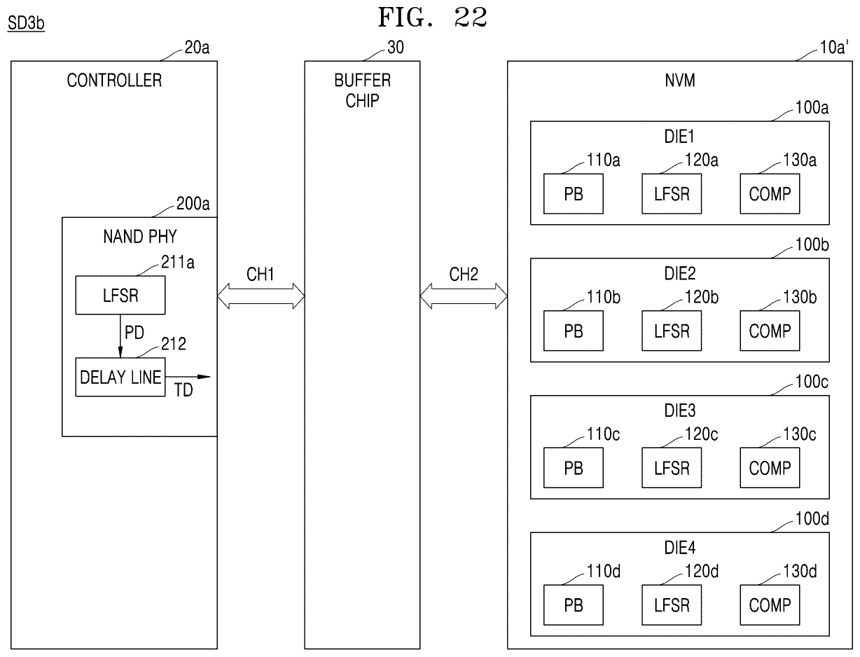

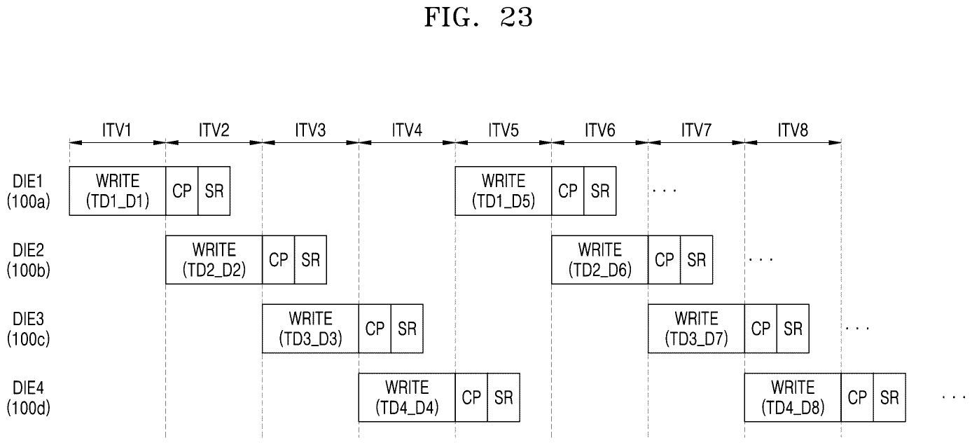

FIG. 22 is a block diagram showing a storage device SD3b according to one or more embodiments. FIG. 23 is a timing diagram illustrating an example of a write training operation of first to fourth memory dies 100a to 100d of FIG. 22, according to one or more embodiments.

Referring to FIGS. 22 and 23 together, the storage device SD3b may include the non-volatile memory 10a', the controller 20a, and the buffer chip 30. The storage device SD3b may correspond to a modified example of the storage device SD3 of FIG. 19. The non-volatile memory 10a′ may be a QDP including the first to fourth memory dies 100a to 100d.

When the storage device SD3b includes the buffer chip 30, a write training operation may include a first write training operation between the controller 20a and the buffer chip 30 and a second write training operation between the buffer chip 30 and the non-volatile memory 10a'. At this time, the second writing training operation may be performed similarly as those of the embodiments described above with reference to FIGS. 1 to 18.

Hereinafter, descriptions will be given based on the first write training operation.

The first write training operation may be performed during a first write training interval including the first to eighth intervals ITV1 to ITV8. In the first interval ITV1, the first memory die 100a may perform a write operation WRITE regarding first training data TD1_D1 corresponding to the first delay value D1. In a second interval ITV2, the first memory die 100a may perform a comparison operation CP for comparing the first training data TD1_D1 with the first pattern data PD1, and subsequently perform a status read operation SR for transmitting the first pass/fail value PF1 to the controller 20a through the buffer chip 30. In the second interval ITV2, the second memory die 100b may perform a write operation WRITE regarding second training data TD2_D2 corresponding to the second delay value D2. In this regard, in the second interval ITV2, the comparison operation CP and the status read operation SR of the first memory die 100a and the write operation WRITE of the second memory die 100b may be performed in parallel.

In the third interval ITV3, the second memory die 100b may perform a comparison operation CP for comparing the second training data TD2_D2 with the second pattern data PD2 and, subsequently, a status read operation SR for transmitting the second pass/fail value PF2 to the controller 20a through the buffer chip 30. In the third interval ITV3, the third memory die 100c may perform a write operation WRITE regarding third training data TD3_D3 corresponding to the third delay value D3. In this regard, in the third interval ITV3, the comparison operation CP and the status read operation SR of the second memory die 100b and the write operation WRITE of the third memory die 100c may be performed in parallel.

In the fourth interval ITV4, the third memory die 100c may perform a comparison operation CP for comparing the third training data TD3_D3 with third pattern data PD3 and, subsequently, a status read operation SR for transmitting the third pass/fail value PF3 to the controller 20a through the buffer chip 30. In the fourth interval ITV4, the fourth memory die 100d may perform a write operation WRITE regarding fourth training data TD4_D4 corresponding to the fourth delay value D4. In this regard, in the fourth interval ITV4, the comparison operation CP and the status read operation SR of the third memory die 100c and the write operation WRITE of the fourth memory die 100d may be performed in parallel.

In the fifth interval ITV5, the fourth memory die 100d may perform a comparison operation CP for comparing the fourth training data TD4_D4 with fourth pattern data PD4 and, subsequently, a status read operation SR for transmitting the fourth pass/fail value PF4 to the controller 20a through the buffer chip 30. In the fifth interval ITV5, the first memory die 100a may perform a write operation WRITE regarding first training data TD1_D5 corresponding to the fifth delay value D5. In this regard, in the fifth interval ITV5, the comparison operation CP and the status read operation SR of the fourth memory die 100d and the write operation WRITE of the first memory die 100a may be performed in parallel.

In the sixth interval ITV6, the first memory die 100a may perform a comparison operation CP for comparing the first training data TD1_D5 with the first pattern data PD1, and subsequently perform a status read operation SR for transmitting the first pass/fail value PF1 to the controller 20a through the buffer chip 30. In the sixth interval ITV6, the second memory die 100b may perform a write operation WRITE regarding second training data TD2_D6 corresponding to the sixth delay value D6. In this regard, in the sixth interval ITV6, the comparison operation CP and the status read operation SR of the first memory die 100a and the write operation WRITE of the second memory die 100b may be performed in parallel.

In the seventh interval ITV7, the second memory die 100b may perform a comparison operation CP for comparing the second training data TD2_D6 with the second pattern data PD2 and, subsequently, a status read operation SR for transmitting the second pass/fail value PF2 to the controller 20a through the buffer chip 30. In the seventh interval ITV7, the third memory die 100c may perform a write operation WRITE regarding third training data TD3_D7 corresponding to the seventh delay value D7. In this regard, in the seventh interval ITV7, the comparison operation CP and the status read operation SR of the second memory die 100b and the write operation WRITE of the third memory die 100c may be performed in parallel.

In the eighth interval ITV8, the third memory die 100c may perform a comparison operation CP for comparing the third training data TD3_D7 with third pattern data PD3 and, subsequently, a status read operation SR for transmitting the third pass/fail value PF3 to the controller 20a through the buffer chip 30. In the eighth interval ITV8, the fourth memory die 100d may perform a write operation WRITE regarding fourth training data TD4_D8 corresponding to eighth delay value D8. In this regard, in the eighth interval ITV8, the comparison operation CP and the status read operation SR of the third memory die 100c and the write operation WRITE of the fourth memory die 100d may be performed in parallel.

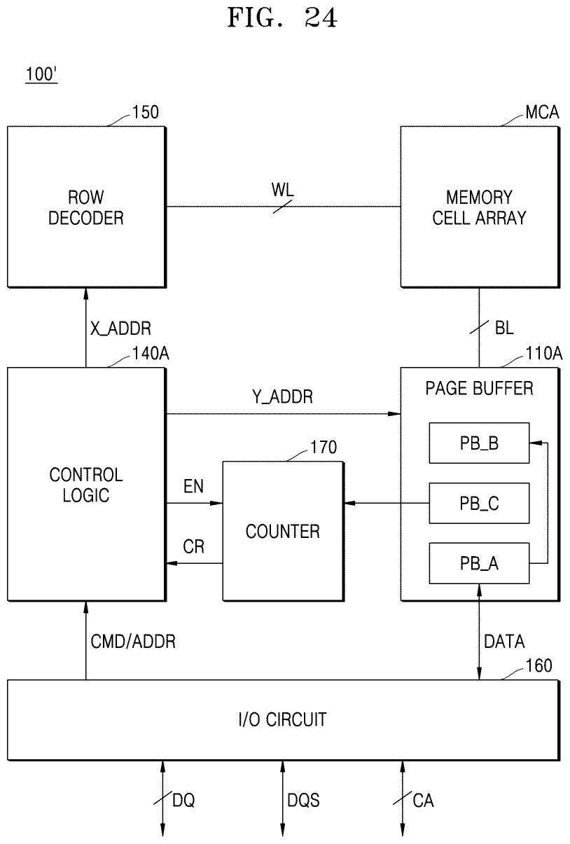

FIG. 24 is a block diagram showing a memory die 100′ according to one or more embodiments.

Referring to FIGS. 1, 4, and 24 together, the memory die 100′ may include the memory cell array MCA, a page buffer 110A, a control logic 140A, the row decoder 150, the input/output circuit 160, and a counter 170. For example, the memory die 100′ may correspond to the first memory die 100A or the second memory die 100B of FIG. 1. For example, the page buffer 110A and the counter 170 may constitute or be included in the write training module WTa or the write training module WTb.

Although the counter 170 is illustrated as a separate component in FIG. 42, the disclosure is not limited thereto. According to some embodiments, the counter 170 may be included in the control logic 140A. According to some embodiments, the counter 170 may be included in the input/output circuit 160. According to some embodiments, the counter 170 may be included in the page buffer 110A. The memory die 100′ may correspond to a modified example of the memory die 100 of FIG. 2, and hereinafter, differences from the memory die 100 of FIG. 2 will be mainly described.

The page buffer 110A may include a first page buffer PB_A, a second page buffer PB_B, and a third page buffer PB_C. According to one or more embodiments, the first page buffer PB_A may correspond to a portion of the page buffer 110A (e.g., one of cache latches, sensing latches, forcing latches, upper bit latches, or lower bit latches), the second page buffer PB_B may correspond to another portion of the page buffer 110A (e.g., another one of the cache latches, the sensing latches, the forcing latches, the upper bit latches, or the lower bit latches), and the third page buffer PB_C may correspond to yet another portion of the page buffer 110A (e.g., yet another one of the cache latches, the sensing latches, the forcing latches, the upper bit latches, or the lower bit latches). For example, the first page buffer PB_A may include a plurality of cache latches, the second page buffer PB_B may include a plurality of upper bit latches, e.g., M-latches, and the third page buffer PB_C may include a plurality of lower bit latches, e.g., L-latches.

During writing training, the input/output circuit 160 may receive a write command that instructs a program operation from the controller 20 through the data signal DQ or the command/address signal CA and may transmit a received write command and an address to the control logic 140A. Next, the input/output circuit 160 may receive reference training data from the controller 20 through the data signal DQ and transmit received reference training data to the first page buffer PB_A.

Next, the input/output circuit 160 may receive a first operation command instructing a dumping operation of the reference training data from the controller 20 and transmit a received first operation command to the control logic 140A. The control logic 140A may control the page buffer 110A to dump the reference training data stored in the first page buffer PB_A into the second page buffer PB_B in response to the first operation command.

Next, the input/output circuit 160 may receive a write command that instructs a program operation from the controller 20 through the data signal DQ or the command/address signal CA and may transmit a received write command and an address to the control logic 140A. Next, the input/output circuit 160 may receive training data from the controller 20 through the data signal DQ and transmit received training data to the first page buffer PB_A.

Next, the input/output circuit 160 may receive a second operation command instructing logic calculations of training data and the reference training data from the controller 20 and transmit a received second operation command to the control logic 140A. The control logic 140A may perform a logical operation, e.g., an XOR operation, on the training data stored in the first page buffer PB_A and the reference training data stored in the second page buffer PB_B, in response to the second operation command, and store a result of the XOR operation in the third page buffer PB_C. For example, when the training data corresponds to the reference training data, the result of the XOR operation may be logic 0, and, when the training data does not correspond to the reference training data, the result of the XOR operation may be logic 1. In this way, it may be determined based on a result of the XOR operation whether the training data matches the reference training data.

Next, the input/output circuit 160 may receive a third operation command instructing a counting operation from the controller 20 and transmit a received third operation command to the control logic 140A. The control logic 140A may generate an enable signal EN in response to the third operation command and provide the generated enable signal EN to the counter 170. The counter 170 may count values corresponding to a first logic level from among results of the XOR operation stored in the third page buffer PB_C in response to the enable signal EN and provide a counting result CR to the control logic 140A. For example, the first logic level may correspond to logic 1 or logic 0. The control logic 140A may generate a pass/fail value by determining whether training data is pass/fail based on the counting result CR.

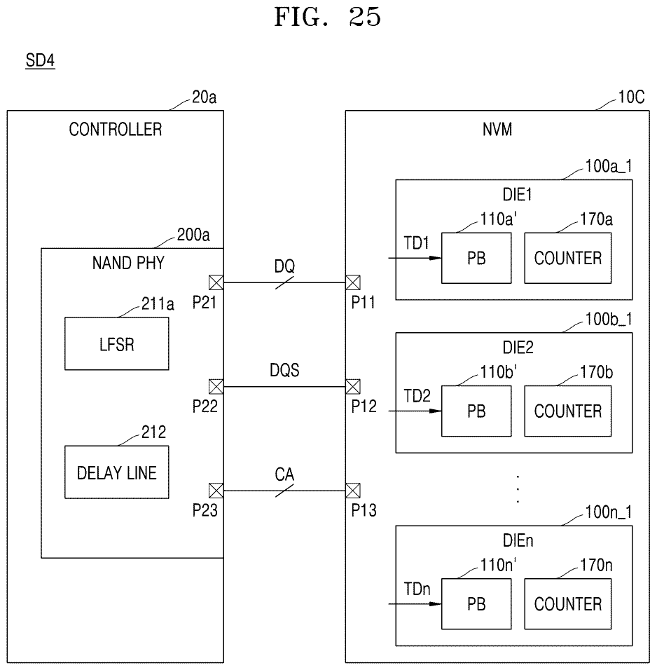

FIG. 25 is a block diagram showing a storage device SD4 according to one or more embodiments.

Referring to FIG. 25, the storage device SD4 may include a non-volatile memory 10C and the controller 20a, and the non-volatile memory 10C and the controller 20a may communicate with each other in an SCA manner in which commands and addresses are transmitted separately from data. For example, the non-volatile memory 10C may correspond to an example of the non-volatile memory 10 of FIG. 1, and the controller 20a may correspond to an example of the controller 20 of FIG. 1. The non-volatile memory 10C may include first to n-th memory dies 100a_1 to 100n_1, where n is a positive integer. The non-volatile memory 10C may further include the plurality of pins P11 to P13. However, the disclosure is not limited thereto, and the non-volatile memory 10C and the controller 20a may also transmit and receive commands, addresses, and data through lines for the data signal DQ.

The first memory die 100a_1 may include a page buffer 110a′ and a counter 170a. The page buffer 110a′ may sequentially receive the reference training data and the first training data TD1 from the controller 20a, store the reference training data and the first training data TD1 in first and second page buffers (e.g., the first page buffer PB_A and the second page buffer PB_B of FIG. 24), respectively, and store a result of an XOR operation for the reference training data and the first training data TD1 in a third page buffer (e.g., the third page buffer PB_C of FIG. 24). The counter 170a may count values corresponding to a first logic level from among results of the XOR operation stored in the third page buffer. The first memory die 100a_1 may generate a pass/fail value by determining whether the first training data TD1 is pass/fail based on a counting result.

A second memory die 100b_1 may include a page buffer 110b′ and a counter 170b. The page buffer 110b′ may sequentially receive the reference training data and the second training data TD2 from the controller 20a, store the reference training data and the second training data TD2 in the first and second page buffers, respectively, and store results of an XOR operation for the reference training data and second training data TD2 in the third page buffer. The counter 170b may count values corresponding to a first logic level from among results of the XOR operation stored in the third page buffer. The second memory die 100b_1 may generate a pass/fail value by determining whether the second training data TD2 is pass/fail based on a counting result.

The n-th memory die 100n_1 may include a page buffer 110n′ and a counter 170n. The page buffer 110n′ may sequentially receive the reference training data and n-th training data TDn from the controller 20a, store the reference training data and the n-th training data TDn in the first and second page buffers, respectively, and store results of an XOR operation for the reference training data and n-th training data TDn in the third page buffer. The counter 170n may count values corresponding to a first logic level from among results of the XOR operation stored in the third page buffer. The n-th memory die 100n_1 may generate a pass/fail value by determining whether the n-th training data TDn is pass/fail based on a counting result.

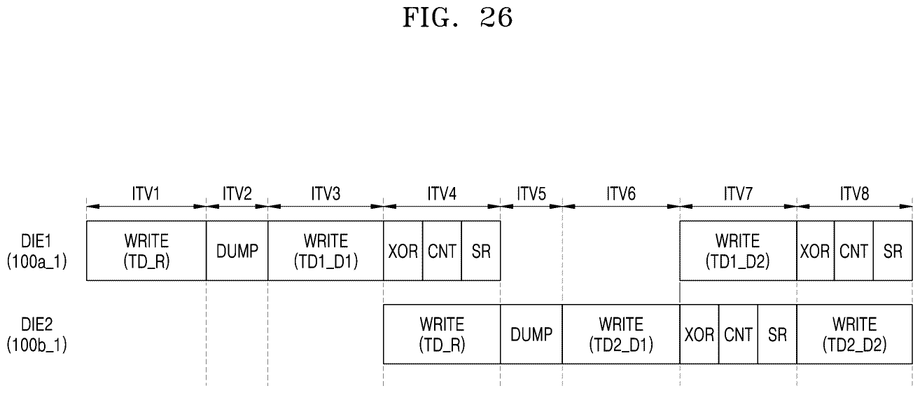

FIG. 26 is a timing diagram illustrating a write training operation of the first memory die 100a_1 and the second memory die 100b_1 of FIG. 25, according to one or more embodiments.

Referring to FIGS. 24 to 26 together, a write training operation may be performed during the write training interval including the first to eighth intervals ITV1 to ITV8. In the first interval ITV1, the first memory die 100a_1 may perform a write operation WRITE for reference training data TD_R. In detail, the first memory die 100a_1 may receive a first command and an address instructing a program operation from the controller 20a, subsequently receive the reference training data TD_R, and store the received reference training data TD_R in the first page buffer PB_A of the page buffer 110a′.

In the second interval ITV2, the first memory die 100a_1 may perform a dumping operation DUMP to dump the reference training data TD_R stored in the first page buffer PB_A into the second page buffer PB_B. In detail, the first memory die 100a_1 may receive a first operation command instructing a dumping operation of the reference training data TD_R from the controller 20a and perform a dumping operation DUMP in response to the first operation command.

In the third interval ITV3, the first memory die 100a_1 may perform a write operation WRITE for the first training data TD1_D1. In detail, the first memory die 100a_1 may receive a first command and an address instructing a program operation from the controller 20a, subsequently receive the first training data TD1_D1, and store the received first training data TD1_D1 in the first page buffer PB_A of the page buffer 110a′. For example, the first training data TD1_D1 may correspond to a training pattern having a delay corresponding to the first delay value D1 of a delay locked loop or a phased locked loop relative to the data strobe signal DQS.

In the fourth interval ITV4, the first memory die 100a_1 may sequentially perform an XOR operation XOR, a counting operation CNT, and a status read operation SR. In detail, the first memory die 100a_1 may receive a second operation command instructing an XOR operation from the controller 20a, perform an XOR operation on the first training data TD1_D1 stored in the first page buffer PB_A and the reference training data TD_R stored in the second page buffer PB_B in response to the second operation command, and store results of the XOR operation in the third page buffer PB_C. Next, the first memory die 100a_1 may receive a third operation command instructing a counting operation from the controller 20a, count values corresponding to a first logic level from among the results of the XOR operation stored in the third page buffer PB_C in response to the third operation command, and determine whether the first training data TD1_D1 is pass/fail based on the counting result CR, thereby generating a first pass/fail value. Next, the first memory die 100a_1 may receive a status read command requesting the first pass/fail value and transmit the first pass/fail value to the controller 20a in response to a received status read command.

Also, in the fourth interval ITV4, the second memory die 100b_1 may perform a write operation WRITE for the reference training data TD_R. In detail, the second memory die 100b_1 may receive a first command and an address instructing a program operation from the controller 20a, subsequently receive the reference training data TD_R, and store the received reference training data TD_R in the first page buffer PB_A of the page buffer 110b′. In this regard, in the fourth interval ITV4, the XOR operation XOR, the counting operation CNT, and the status read operation SR of the first memory die 100a_1 and the write operation WRITE of the second memory die 100b_1 may be performed in parallel.

In the fifth interval ITV5, the second memory die 100b_1 may perform a dumping operation DUMP to dump the reference training data TD_R stored in the first page buffer PB_A into the second page buffer PB_B. In detail, the second memory die 100b_1 may receive a first operation command instructing a dumping operation of the reference training data TD_R from the controller 20a and perform a dumping operation DUMP in response to the first operation command.

In the sixth interval ITV6, the second memory die 100b_1 may perform a write operation WRITE for the second training data TD2_D1. In detail, the second memory die 100b_1 may receive a first command and an address instructing a program operation from the controller 20a, subsequently receive the second training data TD2_D1, and store the received second training data TD2_D1 in the first page buffer PB_A of the page buffer 110b′. For example, the second training data TD2_D1 may correspond to a training pattern having a delay corresponding to the first delay value D1 of a delay locked loop or a phased locked loop relative to the data strobe signal DQS.

In the seventh interval ITV7, the first memory die 100a_1 may perform a write operation WRITE for the first training data TD1_D2. In detail, the first memory die 100a_1 may receive a first command and an address instructing a program operation from the controller 20a, subsequently receive the first training data TD1_D2, and store the received first training data TD1_D2 in the first page buffer PB_A of the page buffer 110a′. For example, the first training data TD1_D2 may correspond to a training pattern having a delay corresponding to the second delay value D2 of a delay locked loop or a phased locked loop relative to the data strobe signal DQS.

Also, in the seventh interval ITV7, the second memory die 100b_1 may sequentially perform the XOR operation XOR, the counting operation CNT, and the status read operation SR. In detail, the second memory die 100b_1 may receive a second operation command instructing an XOR operation from the controller 20a, perform an XOR operation on the second training data TD2_D1 stored in the first page buffer PB_A and the reference training data TD_R stored in the second page buffer PB_B in response to the second operation command, and store results of the XOR operation in the third page buffer PB_C. Next, the second memory die 100b_1 may receive a third operation command instructing a counting operation from the controller 20a, count values corresponding to a first logic level from among the results of the XOR operation stored in the third page buffer PB_C in response to the third operation command, and determine whether the second training data TD2_D1 is pass/fail based on the counting result CR, thereby generating a second pass/fail value. Next, the second memory die 100b_1 may receive a status read command requesting the second pass/fail value and transmit the second pass/fail value to the controller 20a in response to a received status read command. In this regard, in the seventh interval ITV7, the write operation WRITE of the first memory die 100a_1 and the XOR operation XOR, the counting operation CNT, and the status read operation SR of the second memory die 100b_1 may be performed in parallel.

In the eighth interval ITV8, the first memory die 100a_1 may sequentially perform the XOR operation XOR, the counting operation CNT, and the status read operation SR. In detail, the first memory die 100a_1 may receive a second operation command instructing an XOR operation from the controller 20a, perform an XOR operation on the second training data TD2_D2 stored in the first page buffer PB_A and the reference training data TD_R stored in the second page buffer PB_B in response to the second operation command, and store results of the XOR operation in the third page buffer PB_C. Next, the first memory die 100a_1 may receive a third operation command instructing a counting operation from the controller 20a, count values corresponding to a first logic level from among the results of the XOR operation stored in the third page buffer PB_C in response to the third operation command, and determine whether the first training data TD1_D2 is pass/fail based on the counting result CR, thereby generating the second pass/fail value. Next, the first memory die 100a_1 may receive a status read command requesting the first pass/fail value and transmit the first pass/fail value to the controller 20a in response to a received status read command.

In the eighth interval ITV8, the second memory die 100b_1 may perform a write operation WRITE for the second training data TD2_D2. In detail, the second memory die 100b_1 may receive a first command and an address instructing a program operation from the controller 20a, subsequently receive the second training data TD2_D2, and store the received second training data TD2_D2 in the first page buffer PB_A of the page buffer 110b′. For example, the second training data TD2_D2 may correspond to a training pattern having a delay corresponding to the second delay value D2 of a delay locked loop or a phased locked loop relative to the data strobe signal DQS. In this regard, in the eighth interval ITV8, the XOR operation XOR, the counting operation CNT, and the status read operation SR of the first memory die 100a_1 and the write operation WRITE of the second memory die 100b_1 may be performed in parallel.

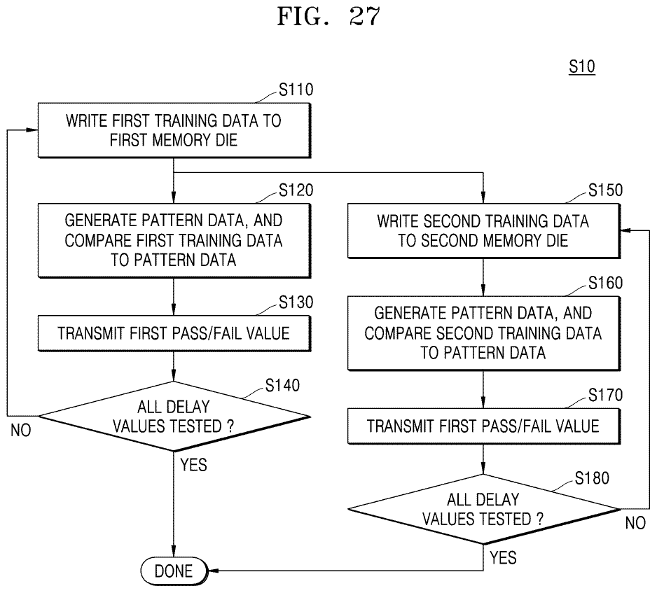

FIG. 27 is a flowchart showing a method S10 of operating a non-volatile memory, according to one or more embodiments.

Referring to FIG. 27, the method S10 of operating a non-volatile memory may include a method of write training a non-volatile memory. The method S10 of operating a non-volatile memory according to the present embodiment may include a plurality of operations performed in time series in the non-volatile memory 10 of FIG. 1, the non-volatile memory 10A of FIG. 3, or the non-volatile memory 10B of FIG. 4, and thus descriptions given above with reference to FIGS. 1 to 21 may also be applied to the present embodiment.

A write training operation for a first memory die (e.g., 100a of FIG. 3 or FIG. 4) may include operations S110 to S140. In operation S110, first training data may be written to the first memory die. In operation S120, the first memory die may generate pattern data and compare the pattern data with the first training data. In operation S130, the first memory die may transmit a first pass/fail value to a controller. In operation S140, whether testing for all delay values is completed may be determined. When it is determined that not all delay values are tested, operations S110 to S140 may be performed repeatedly. On the other hand, when it is determined that testing is completed for all delay values, the write training operation for the first memory die may be terminated.

A write training operation for a second memory die (e.g., 100b of FIG. 3 or FIG. 4) may include operations S150 to S180. In operation S150, second training data may be written to the second memory die. According to one or more embodiments, operation S150 may be performed in parallel with operation S120. According to one or more embodiments, operation S150 may be performed in parallel with operation S130. According to one or more embodiments, operation S150 may be performed in parallel with operations S120 and S130. In operation S160, the second memory die may generate pattern data and compare the pattern data with the second training data. In operation S170, the second memory die may transmit a second pass/fail value to the controller. In operation S180, whether testing for all delay values is completed may be determined. When it is determined that not all delay values are tested, operations S150 to S180 may be performed repeatedly. On the other hand, when it is determined that testing is completed for all delay values, the write training operation for the second memory die may be terminated.

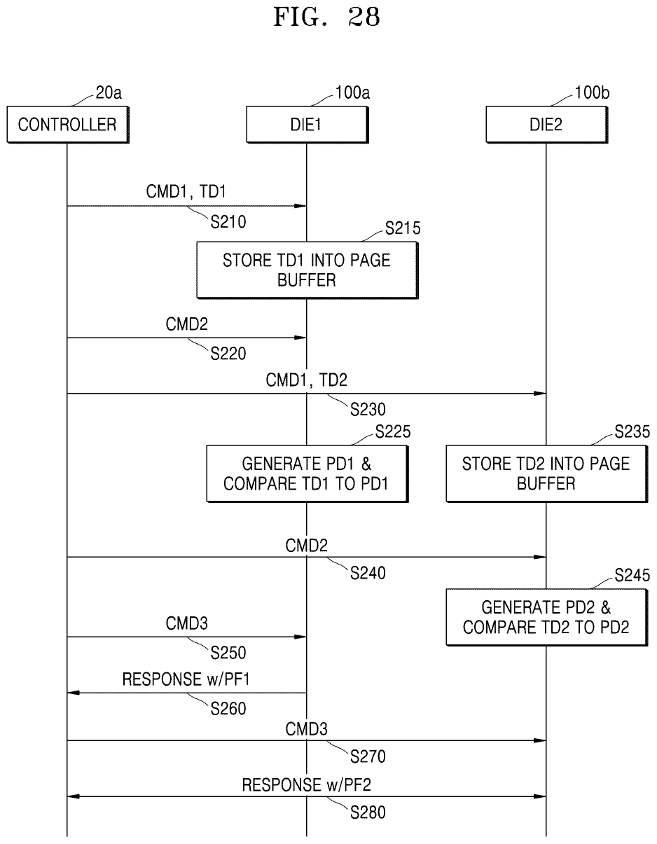

FIG. 28 is a flowchart showing an operation method between the controller 20a, the first memory die 100a, and the second memory die 100b, according to one or more embodiments.

Referring to FIG. 28, in operation S210, the controller 20a may transmit a first command CMD1 instructing a write operation and the first training data TD1 to the first memory die 100a. In operation S215, the first memory die 100a may store the first training data TD1 in a page buffer in response to the first command CMD1.

In operation S220, the controller 20a may transmit a second command CMD2 instructing a comparison operation to the first memory die 100a. In operation S230, the controller 20a may transmit the first command CMD1 instructing a write operation and the second training data TD2 to the second memory die 100b. According to one or more embodiments, operation S220 may be performed first and operation S230 may be performed later. According to one or more embodiments, operation S230 may be performed first and operation S220 may be performed later. According to one or more embodiments, a time interval during which operation S220 is performed and a time interval during which operation S230 is performed may at least partially overlap each other.

In operation S225, the first memory die 100a may generate the first pattern data PD1 in response to the second command CMD2 and compare the first training data TD1 with the first pattern data PD1. In operation S235, the second memory die 100b may store the second training data TD2 in a page buffer in response to the first command CMD1. According to one or more embodiments, a time interval during which operation S225 is performed and a time interval during which operation S235 is performed may at least partially overlap each other.

In operation S240, the controller 20a may transmit the second command CMD2 instructing a comparison operation to the second memory die 100b. In operation S245, the second memory die 100b may generate the second pattern data PD2 in response to the second command CMD2 and compare the second training data TD2 with the second pattern data PD2. In operation S250, the controller 20a may transmit a third command CMD3 instructing a status read operation to the first memory die 100a. In operation S260, the first memory die 100a may transmit a response including the first pass/fail value PF1 to the controller 20a in response to the third command CMD3. In operation S270, the controller 20a may transmit the third command CMD3 instructing a status read operation to the second memory die 100b. In operation S280, the second memory die 100b may transmit a response including the second pass/fail value PF2 to the controller 20a in response to the third command CMD3.

According to one or more embodiments, operation S240 may be performed first and operation S250 may be performed later. According to one or more embodiments, operation S250 may be performed first and operation S240 may be performed later.

According to one or more embodiments, a time interval during which operation S245 is performed and a time interval during which operations S250 and S260 are performed may at least partially overlap each other.

According to one or more embodiments, first to third commands CMD1 to CMD3 and responses may be transmitted through lines for the command/address signal CA, and the first training data TD1 and the second training data TD2 may be transmitted through lines for the data signal DQ. According to one or more embodiments, the first to third commands CMD1 to CMD3, responses, and the first training data TD1 and the second training data TD2 may be transmitted sequentially through the lines for the data signal DQ.

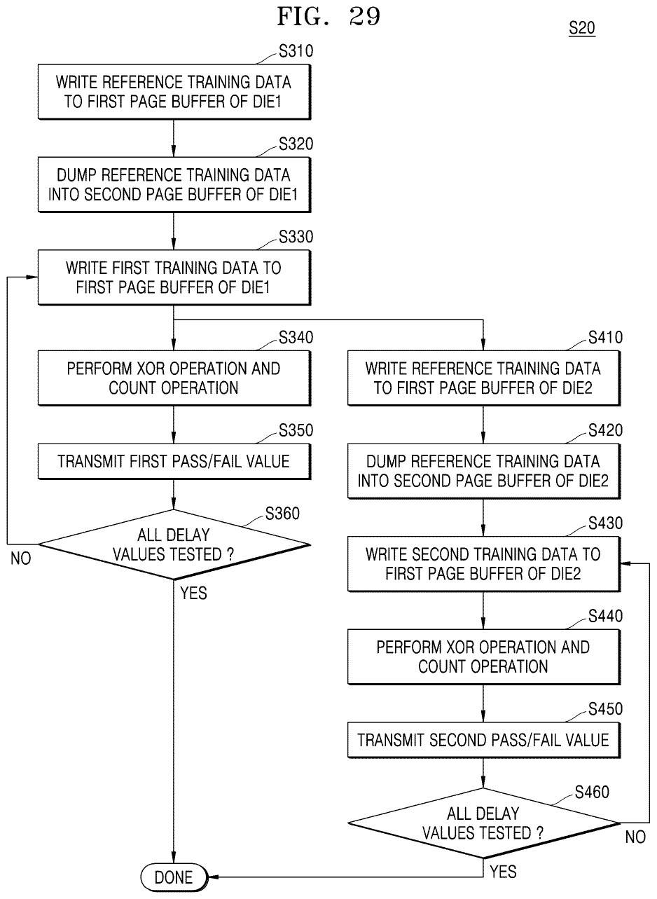

FIG. 29 is a flowchart showing a method S20 of operating a non-volatile memory, according to one or more embodiments.

Referring to FIG. 29, the method S20 of operating a non-volatile memory may include a method of write training a non-volatile memory. The method S20 of operating a non-volatile memory according to the present embodiment may include a plurality of operations performed in time series in the non-volatile memory 10 of FIG. 1 or the non-volatile memory 10C of FIG. 25, and thus descriptions given above with reference to FIGS. 1 and 24 to 26 may also be applied to the present embodiment.

A write training operation for the first memory die (e.g., 100a_1 of FIG. 25) may include operations S310 to S360. In operation S310, the reference training data TD_R may be written to the first page buffer PB_A of the first memory die 100a_1. In operation S320, the first memory die 100a_1 may dump the reference training data TD_R stored in the first page buffer PB_A to the second page buffer PB_B of the first memory die 100a_1. In operation S330, the first training data TD1 may be stored in the first page buffer PB_A of the first memory die 100a_1. In operation S340, an XOR operation may be performed on the first training data TD1 stored in the first page buffer PB_A and the reference training data TD_R stored in the second page buffer PB_B, and a counting operation may be performed on results of the XOR operation. In operation S350, the first memory die 100a_1 may transmit a first pass/fail value for the first training data TD1 to the controller 20a. In operation S360, it may be determined whether testing for all delay values is completed. When it is determined that not all delay values are tested, operations S330 to S360 may be performed repeatedly. On the other hand, when it is determined that testing is completed for all delay values, the write training operation for the first memory die may be terminated.

A write training operation for the second memory die (e.g., 100b_1 of FIG. 25) may include operations S410 to S460. In operation S410, the reference training data TD_R may be written to the first page buffer PB_A of the second memory die 100b_1.

According to one or more embodiments, operation S410 may be performed in parallel with at least one of operations S340 and S350. In operation S420, the second memory die 100b_1 may dump the reference training data TD_R stored in the first page buffer PB_A to the second page buffer PB_B of the second memory die 100b_1. According to one or more embodiments, operation S420 may be performed in parallel with at least one of operations S340 and S350. In operation S430, the second training data TD2 may be stored in the first page buffer PB_A of the second memory die 100b_1. According to one or more embodiments, operation S430 may be performed in parallel with at least one of operations S340 and S350.

In operation S440, an XOR operation may be performed on the second training data TD2 stored in the first page buffer PB_A and the reference training data TD_R stored in the second page buffer PB_B, and a counting operation may be performed on results of the XOR operation. In operation S450, the second memory die 100b_1 may transmit a second pass/fail value for the second training data TD2 to the controller 20a. In operation S460, it may be determined whether testing for all delay values is completed. When it is determined that not all delay values are tested, operations S430 to S460 may be performed repeatedly. On the other hand, when it is determined that testing is completed for all delay values, the write training operation for the second memory die may be terminated.

According to some embodiments, each of the first training data and the second training data corresponds to a first delay value, and the third training data corresponds to a second delay value that is different from the first delay value.

According to some embodiments, the first page buffer comprises a first latch, a second latch, and a third latch, and the first memory die is configured to store the reference training data in the first latch, store the first training data in the second latch, and store a result of the logical operation in the third latch.

According to some embodiments, the first latch corresponds to one of a cache latch, an upper bit latch, a lower bit latch, a sensing latch, and a forcing latch, the second latch corresponds to another one of the cache latch, the upper bit latch, the lower bit latch, the sensing latch, and the forcing latch, and the third latch corresponds to yet another one of the cache latch, the upper bit latch, the lower bit latch, the sensing latch, and the forcing latch.

According to some embodiments, the first memory die further comprises: a first pattern generator configured to generate first pattern data; and a first comparator configured to generate the first pass/fail value by comparing the first training data with the first pattern data, and the second memory die further comprises: a second pattern generator configured to generate second pattern data; and a second comparator configured to generate the second pass/fail value regarding second training data by comparing the second training data with the second pattern data.

According to some embodiments, each of the first pattern generator and the second pattern generator comprises a linear feedback shift register.

While the disclosure has been particularly shown and described with reference to example embodiments thereof, it will be understood that various changes in form and details may be made therein without departing from the spirit and scope of the following claims and their equivalents.

What is claimed is:

1. A non-volatile memory device comprising:
a plurality of memory dies connected to a controller through a first channel and configured to perform write training based on training data received from the controller,
wherein the plurality of memory dies comprise a first memory die and a second memory die each comprising non-volatile memory cells,
wherein the first memory die is configured to receive first training data from the controller in a first interval and compare the first training data with first pattern data and transmit a first pass/fail value regarding the first training data to the controller, in a second interval after the first interval, and
wherein the second memory die is configured to receive second training data from the controller in the second interval.

2. The non-volatile memory device of claim 1, wherein the first memory die further comprises a first page buffer configured to store the first training data, and
wherein the second memory die further comprises a second page buffer configured to store the second training data.

3. The non-volatile memory device of claim 2, wherein the second memory die is configured to compare the second training data with second pattern data and transmit a second pass/fail value regarding the second training data to the controller, in a third interval after the second interval.

4. The non-volatile memory device of claim 2, wherein the first memory die is further configured to receive a first command and the first training data from the controller, and, store the first training data in the first page buffer in response to the first command.

5. The non-volatile memory device of claim 2, wherein the first memory die is further configured to receive a second command from the controller, and compare the first training data with the first pattern data in response to the second command,.

6. The non-volatile memory device of claim 5, wherein the first memory die further comprises:
a pattern generator configured to generate the first pattern data in response to the second command; and
a comparator configured to compare the first training data received from the first page buffer with the first pattern data received from the pattern generator in response to the second command.

7. The non-volatile memory device of claim 6, wherein the pattern generator comprises a linear feedback shift register.

8. The non-volatile memory device of claim 1, wherein the first memory die is further configured to receive a third command from the controller, and, transmit the first pass/fail value to the controller in response to the third command.

9. The non-volatile memory device of claim 1, wherein the first training data corresponds to a first delay value, and the second training data corresponds to the first delay value, and
wherein the first memory die is further configured to receive third training data corresponding to a second delay value different from the first delay value from the controller in a third interval after the second interval.

10. The non-volatile memory device of claim 9, further comprising a data strobe pin configured to receive a data strobe signal from the controller,
wherein the first training data comprises a training pattern having a delay corresponding to the first delay value with respect to the data strobe signal, and
wherein the third training data comprises a training pattern having a delay corresponding to the second delay value with respect to the data strobe signal.

11. The non-volatile memory device of claim 1, further comprising:
a command/address pin configured to receive a command and an address from the controller via a command/address signal line;
a data pin configured to receive data from the controller through a data signal line; and
a data strobe pin configured to receive a data strobe signal from the controller via a data strobe line,
wherein the first training data and the second training data are received through the data pin, and
wherein the first pass/fail value is transmitted through the command/address pin.

12. The non-volatile memory device of claim 1, further comprising:
a data pin configured to receive a command, an address, and data from the controller through a data signal line; and
a data strobe pin configured to receive a data strobe signal from the controller via a data strobe line,
wherein the first training data and the second training data are received through the data pin, and
wherein the first pass/fail value is transmitted through the data pin.

13. A non-volatile memory device comprising:
a buffer chip connected to a controller through a first channel; and
a plurality of memory dies connected to the buffer chip through a second channel and configured to perform a first write training between the controller and the buffer chip during a first write training interval,
wherein the plurality of memory dies comprise:
a first memory die configured to receive, from the controller through the buffer chip, first training data corresponding to a first delay value during a first interval of the first write training interval; and
a second memory die configured to receive, from the controller through the buffer chip, second training data corresponding to a second delay value different from the first delay value during a second interval of the first write training interval, and
wherein the first memory die is configured to generate a first pass/fail value for the first training data and transmit the first pass/fail value to the controller through the buffer chip, during the second interval of the first write training interval.

14. The non-volatile memory device of claim 13, wherein the second memory die is configured to generate a second pass/fail value for the second training data and transmit the second pass/fail value to the controller through the buffer chip, after the second interval of the first write training interval.

15. The non-volatile memory device of claim 14, wherein the first memory die comprises:
a first page buffer configured to store the first training data;
a first pattern generator configured to generate first pattern data; and
a first comparator configured to generate the first pass/fail value by comparing the first training data with the first pattern data, and
wherein the second memory die comprises:
a second page buffer configured to store the second training data;
a second pattern generator configured to generate second pattern data; and
a second comparator configured to generate the second pass/fail value by comparing the second training data with the second pattern data.

16. The non-volatile memory device of claim 13, wherein the plurality of memory dies are further configured to perform second write training between the buffer chip and the plurality of memory dies during a second write training interval,
wherein the first memory die is further configured to receive third training data from the controller through the buffer chip during a first interval of the second write training interval,
wherein the first memory die is further configured to generate a third pass/fail value regarding the third training data, and the second memory die is configured to receive fourth training data from the controller through the buffer chip, during a second interval of the second write training interval, and
wherein the first memory die is configured to receive fifth training data from the controller through the buffer chip, and the second memory die is further configured to generate a fourth pass/fail value regarding the fourth training data, during a third interval of the second write training interval.

17. The non-volatile memory device of claim 16, wherein the third training data and the fourth training data each correspond to a third delay value, and
wherein the fifth training data corresponds to a fourth delay value that is different from the third delay value.

18. A non-volatile memory device comprising:
a plurality of memory dies connected to a controller through a first channel and configured to perform write training based on training data received from the controller,
wherein the plurality of memory dies comprise:
a first memory die comprising a first page buffer, and configured to store reference training data and first training data received from the controller in the first page buffer and generate a first pass/fail value regarding the first training data based on a result of a logical operation for the reference training data and the first training data; and
a second memory die comprising a second page buffer and configured to store the reference training data and second training data received from the controller in the second page buffer and generate a second pass/fail value regarding the second training data based on a result of a logical operation for the reference training data and the second training data, and
wherein, while the first memory die generates the first pass/fail value, the second memory die is configured to receive the reference training data or the second training data.

19. The non-volatile memory device of claim 18, wherein the first memory die is further configured to:
receive the reference training data and store the reference training data in a first region of the first page buffer, during a first interval;
dump the reference training data stored in the first region of the first page buffer to a second region of the first page buffer, during a second interval;
receive the first training data and store the first training data in the first region of the first page buffer, during a third interval; and
generate the first pass/fail value by counting results of logical operations regarding the reference training data and the first training data, during a fourth interval.

20. The non-volatile memory device of claim 19, wherein the second memory die is further configured to:
receive the reference training data and store the reference training data in a first region of the second page buffer, during the fourth interval;
dump the reference training data stored in the first region of the second page buffer to a second region of the second page buffer, during a fifth interval;
receive the second training data and store the second training data in the first region of the second page buffer, during a sixth interval; and
generate the second pass/fail value by counting results of logical operations regarding the reference training data and the second training data, during a seventh interval, and
wherein the first memory die is further configured to receive third training data during the seventh interval.
